(19) United States
(12) Patent Application Publication
(10) Pub. No.: US 2026/0289049 A1
(43) Pub. Date: Sep. 24, 2026

(54) SYSTEM

(71) Applicant: SoftBank Group Corp., Tokyo (JP)

(72) Inventor: Kaito YAMADA, Tokyo (JP)

(73) Assignee: SoftBank Group Corp., Tokyo (JP)

(21) Appl. No.: 19/560,340

(22) Filed: Mar. 9, 2026

(30) Foreign Application Priority Data
Mar. 19, 2025 (JP) 2025-044902

(51) Int. Cl. G06F 30/27; G06N 3/0475; G06N 3/0495

(52) U.S. Cl. CPC G06F 30/27; G06N 3/0475; G06N 3/0495

(57) ABSTRACT

A system includes a processor that is configured to generate a prompt sentence for instructing analysis of each element of a design and application of a prediction algorithm, generate a prompt sentence for instructing collection of an operation history of a user and evaluation of usability based on the collected operation history, and generate a prompt sentence for instructing analysis of a design change and evaluation of a predicted impact of the design change.

### CROSS-REFERENCE TO RELATED APPLICATION

This application is based on and claims priority under 35 USC 119 from Japanese Patent Application No. 2025-044902 filed on Mar. 19, 2025, the disclosure of which is incorporated by reference herein.

### BACKGROUND

### Technical Field

### The Present Disclosure Relates to a System.

### Related Art

Japanese Patent Application Laid-Open (JP-A) No. 2022-180282 discloses a persona chatbot control method executed by at least one processor. The method includes steps of: receiving a user utterance, adding the user utterance to a prompt including a description of a chatbot character and an associated instruction sentence, encoding the prompt, and inputting the encoded prompt to a language model to generate a chatbot utterance responding to the user utterance.

Conventional systems for designing and improving user interfaces and services suffer from several problems. First, a designer or analyst must manually construct analysis procedures and evaluation criteria for each design element, such as layout, components, and textual content, and must then manually apply prediction algorithms or usability evaluation methods. This manual work requires expert knowledge of data analysis and human factors, is time-consuming, and often results in inconsistent quality of evaluation.

Second, conventional systems do not provide a unified mechanism to translate high-level design evaluation intents, such as “analyze design elements,” “evaluate usability from operation history,” or “assess impact of design changes,” into machine-executable instructions for artificial intelligence models. As a result, the interaction between a human user and an AI model is ad hoc, relies heavily on manual prompt authoring, and easily leads to ambiguous or suboptimal analysis results.

Third, when simulated qualitative interviews using artificial intelligence are conducted, there is no systematic way to generate appropriate interview scenarios and to instruct the AI model how to analyze the responses. This makes it difficult to obtain reliable and reproducible qualitative insights across different projects or user segments.

Fourth, prediction results returned by generative AI models or other AI models are often complex, technical, or fragmented, and are not automatically transformed into a presentation format that is easily understandable for general users, such as designers, product managers, or business stakeholders. Consequently, decision-making based on AI output is hindered, and the potential benefit of AI-based prediction and analysis is not fully realized.

Therefore, there is a need for a system that automatically generates structured prompt sentences which instruct AI models to perform analyses of design elements, collection and evaluation of user operation history, assessment of predicted impacts of design changes, execution of simulated qualitative interviews, and transformation of AI prediction results into user-friendly presentations, thereby reducing the burden on users and improving the reliability and usability of AI-assisted design evaluation.

### SUMMARY

In order to solve the above problems, a system according to one embodiment of the invention comprises a processor, wherein the processor is configured to generate a prompt sentence for instructing analysis of each element of a design and application of a prediction algorithm. By automatically generating such a prompt sentence based on the current design data, the processor enables an artificial intelligence model to perform consistent analysis and prediction of design-related metrics without requiring the user to manually compose technical instructions.

The processor is further configured to generate a prompt sentence for instructing collection of an operation history of a user and evaluation of usability based on the collected operation history. By doing so, the processor allows an AI model or analysis engine to be systematically directed to gather relevant interaction logs and to evaluate usability indicators, such as task completion success, error frequency, or interaction efficiency, on the basis of unified prompt semantics.

The processor is also configured to generate a prompt sentence for instructing analysis of a design change and evaluation of a predicted impact of the design change. In this way, when the design is modified, the processor can automatically formulate a prompt that causes an AI model to compare the modified design with a baseline design and to estimate the impact on predetermined performance metrics.

According to another aspect, the processor is configured to generate a prompt sentence for instructing generation of an interview scenario and analysis of responses, in order to conduct a simulated qualitative interview by artificial intelligence. By generating such a prompt sentence, the processor provides a standardized mechanism for defining interview questions, user attributes, and evaluation viewpoints, and for directing the AI model to analyze the generated responses in a structured manner.

According to still another aspect, the processor is configured to generate a prompt sentence for instructing analysis of a prediction result returned by a generative AI model and presentation of the analyzed prediction result to the user in an easy-to-understand format. Through this configuration, the processor can cause a generative AI model or other processing module to reorganize complex prediction outputs into summarized explanations, visual indicators, or narrative descriptions that are comprehensible for non-expert users.

By providing these configurations, the system automatically generates prompt sentences that bridge high-level design evaluation intents and low-level AI operations, thereby enabling unified, repeatable, and user-friendly AI-assisted analysis of designs, usability, design changes, qualitative interviews, and AI prediction results.

The term “system” refers to an arrangement of one or more hardware devices, software components, or a combination thereof, that operates collectively to perform the processing described in the present specification and claims.

The term “processor” refers to any hardware device or combination of hardware devices capable of executing instructions, such as a central processing unit (CPU), a microprocessor, a graphics processing unit (GPU), a digital signal processor (DSP), an application-specific integrated circuit (ASIC), a field-programmable gate array (FPGA), or a combination of these, and may include multiple processing cores or distributed processors.

The term “prompt sentence” refers to a text string or structured textual instruction that is provided to an artificial intelligence model or other processing module in order to request a specific operation, analysis, or generation task, and that encodes, in natural language or a formalized language, the content and intent of such operation, analysis, or generation task.

The term “design” refers to a configuration of elements constituting a user interface or service interface, including at least one of layouts, components, graphical elements, textual content, interaction flows, or presentation styles, which are intended to be presented to or interacted with by a user.

The term “element of a design” refers to an individual component or feature within a design, including, for example, a button, link, input field, image, icon, text block, container, layout region, or interaction control, as well as attributes associated with such component or feature.

The term “prediction algorithm” refers to any computational method or model configured to output an estimated value or distribution of a future or unknown metric, such as a conversion rate, usability score, or user behavior indicator, based on input data that may include design information, user interaction history, or contextual information.

The term “operation history of a user” refers to data indicating past interactions performed by at least one user with a system or service, including, for example, click events, taps, scrolls, form inputs, page transitions, dwell times, errors, or abandonments, together with associated timestamps or contextual metadata.

The term “usability” refers to a quality attribute representing the degree to which a user can use a system or service effectively, efficiently, and satisfactorily to achieve specified goals in a specified context of use, and may include metrics such as task success rate, error rate, interaction time, or subjective satisfaction.

The term “design change” refers to a modification applied to a design, including adding, deleting, moving, resizing, restyling, or otherwise altering one or more elements of the design or their attributes, relative to a baseline or previous version of the design.

The term “predicted impact” refers to an estimated effect of a design change on at least one performance indicator, such as usability, conversion rate, engagement, error occurrence, or other business or user-experience metrics, as inferred by a prediction algorithm or AI model.

The term “simulated qualitative interview” refers to a process in which an artificial intelligence model generates or analyzes natural-language responses that imitate interview-style answers from hypothetical or modeled users, in order to obtain qualitative insights regarding perceptions, opinions, or experiences related to a design or service.

The term “interview scenario” refers to a structured definition of conditions and content for a qualitative interview, including at least one of target user attributes, interview goals, question sets, evaluation viewpoints, or context descriptions, which guide the generation or analysis of interview responses.

The term “response” refers to a piece of output, typically in natural language, that is generated by an artificial intelligence model or another system module as an answer, comment, opinion, or explanation corresponding to an interview scenario, a prompt sentence, or another input.

The term “generative AI model” refers to an artificial intelligence model configured to generate output data, such as text, images, or other content, in response to input data including prompt sentences, and may be implemented as, for example, a large language model, a generative adversarial network, or another generative neural network architecture.

The term “prediction result” refers to output information produced by a generative AI model or other AI model that represents at least one predicted value, distribution, classification, explanation, or recommendation regarding performance, usability, or other characteristics of a design, user behavior, or system state.

The term “easy-to-understand format” refers to a presentation form that is intended to be readily comprehensible by a human user without specialized technical knowledge, and may include one or more of simplified textual explanations, summaries, visual indicators, charts, tables, or structured narratives derived from underlying AI-generated or analytical results.

### BRIEF DESCRIPTION OF THE DRAWINGS

Exemplary embodiments of the present disclosure will be described in detail based on the following figures, wherein:

FIG. 1 is a schematic diagram illustrating an example of a configuration of a data processing system according to a first exemplary embodiment;

FIG. 2 is a schematic diagram illustrating an example of relevant functions of a data processing device and a smart device according to the first exemplary embodiment;

FIG. 3 is a schematic diagram illustrating an example of a configuration of a data processing system according to a second exemplary embodiment;

FIG. 4 is a schematic diagram illustrating an example of relevant functions of a data processing device and smart glasses according to the second exemplary embodiment;

FIG. 5 is a schematic diagram illustrating an example of a configuration of a data processing system according to a third exemplary embodiment;

FIG. 6 is a schematic diagram illustrating an example of relevant functions of a data processing device and a headset-type terminal according to the third exemplary embodiment;

FIG. 7 is a schematic diagram illustrating an example of a configuration of a data processing system according to a fourth exemplary embodiment;

FIG. 8 is a schematic diagram illustrating an example of relevant functions of a data processing device and a robot according to the fourth exemplary embodiment;

FIG. 9 illustrates an emotion map mapping plural emotions;

FIG. 10 illustrates an emotion map mapping plural emotions;

FIG. 11 is a sequence diagram showing the flow of data processing system processing in Example 1;

FIG. 12 is a sequence diagram showing the flow of data processing system processing in Application Example 1;

FIG. 13 is a sequence diagram showing the flow of data processing system processing in Example 2; and

FIG. 14 is a sequence diagram showing the flow of data processing system processing in Application Example 2.

### DETAILED DESCRIPTION

Description follows regarding an example of exemplary embodiments of a system according to technology disclosed herein, with reference to the appended drawings.

First, explanation follows regarding terminology employed in the following description.

In the following exemplary embodiments, a reference-numeral-appended processor (hereinafter simply referred to as “processor”) may be implemented by a single computation unit, and may be implemented by a combination of plural computation units. The processor may be implemented by a single type of computation unit, or may be implemented by a combination of plural types of computation units. Examples of computation unit include a central processing unit (CPU), a graphics processing unit (GPU), a general-purpose computing on graphics processing units (GPGPU), an accelerated processing unit (APU), and the like.

In the following exemplary embodiments, random access memory (RAM) appended with a reference numeral is memory temporarily stored with information, and is employed as working memory by a processor.

In the following exemplary embodiments, reference-numeral-appended storage is a single or plural non-volatile storage devices for storing various programs and various parameters and the like. Examples of non-volatile storage devices include flash memory (such as a solid state drive (SSD)), a magnetic disk (for example, a hard disk), magnetic tape, and the like.

In the following exemplary embodiments, a reference-numeral-appended communication interface (I/F) is an interface including a communication processor and an antenna or the like. The communication I/F has the role of communicating between plural computers. An example of a communication standard applied for the communication I/F is a wireless communication standard, such as a Fifth Generation Mobile Communication System (5G), Wi-Fi (registered trademark), Bluetooth (registered trademark), and the like.

In the following exemplary embodiments “A and/or B” has the same definition as “at least one out of A or B”. Namely, “A and/or B” may mean A alone, may mean B alone, or may mean a combination of A and B. Moreover, similar logic to “A and/or B” is applied when “and/or” is employed to link three or more items in the present specification.

### First Exemplary Embodiment

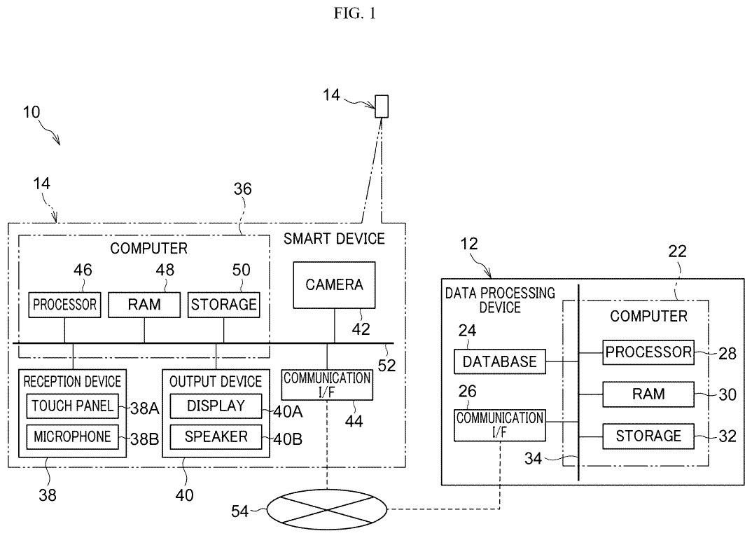

FIG. 1 illustrates an example of a configuration of a data processing system 10 according to a first exemplary embodiment.

As illustrated in FIG. 1, the data processing system 10 includes a data processing device 12 and a smart device 14. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The smart device 14 includes a computer 36, a reception device 38, an output device 40, a camera 42, and a communication I/F 44. The computer 36 includes a processor 46, RAM 48, and storage 50. The processor 46, the RAM 48, and the storage 50 are connected to a bus 52. The reception device 38, the output device 40, the camera 42, and the communication I/F 44 are also connected to the bus 52.

The reception device 38 includes a touch panel 38A, a microphone 38B, and the like for receiving user input. The touch panel 38A receives user input from contact of a pointer (for example, a pen, a finger, or the like) by detecting contact of the pointer. The microphone 38B receives spoken user input by detecting speech of the user. A control unit 46A in the processor 46 transmits data representing the user input received by the touch panel 38A and the microphone 38B to the data processing device 12. A specific processing unit 290 in the data processing device 12 acquires the data indicating the user input.

The output device 40 includes a display 40A, a speaker 40B, and the like for presenting data to a user 20 by outputting the data in an expression format perceivable by the user 20 (for example, audio and/or text). The display 40A displays visual information such as text, images, or the like under instruction from the processor 46. The speaker 40B outputs audio under instruction from the processor 46. The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like.

The communication I/F 44 is connected to the network 54. The communication I/F 44 and the communication I/F 26 perform the role of exchanging various information between the processor 46 and the processor 28 over the network 54.

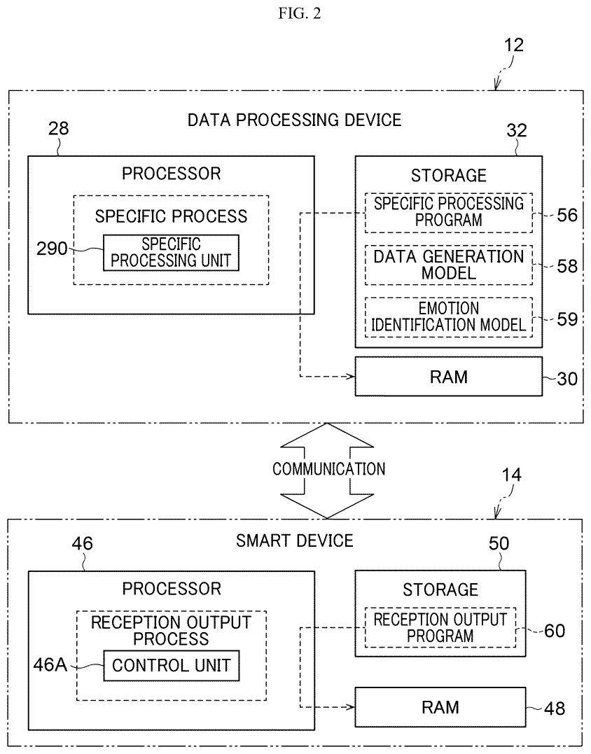

FIG. 2 illustrates an example of relevant functions of the data processing device 12 and the smart device 14.

As illustrated in FIG. 2, specific processing is performed by the processor 28 in the data processing device 12. A specific processing program 56 is stored in the storage 32. The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

A data generation model 58 and an emotion identification model 59 are stored in the storage 32. The data generation model 58 and the emotion identification model 59 are employed by the specific processing unit 290. The specific processing unit 290 uses the emotion identification model 59 to estimate an emotion of a user, and is able to perform the specific processing using the user emotion. In an emotion estimation function (emotion identification function) that uses the emotion identification model 59, various estimations, predictions, and the like are performed related to emotions of the user, include estimating and predicting the emotion of the user, however, there is no limitation to such examples. Moreover, estimation and prediction of emotion also includes, for example, analyzing (parsing) emotions and the like.

Reception and output processing is performed by the processor 46 in the smart device 14. A reception and output program 60 is stored in the storage 50. The reception and output program 60 is employed by the data processing system 10 in combination with the specific processing program 56. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48. Note that a configuration may be adopted in which a similar data generation model and emotion identification model to the data generation model 58 and the emotion identification model 59 are included in the smart device 14, and these models are used to perform similar processing to the specific processing unit 290. The reception and output program is implemented by the processor 46 operating as the control unit 46A according to the reception and output program 60 executed in the RAM 48.

Note that devices other than the data processing device 12 may include the data generation model 58. For example, a server device (for example, a generation server) may include the data generation model 58. In such cases, the data processing device 12 performs communication with the server device including the data generation model 58 to obtain a processing result (prediction result or the like) obtained using the data generation model 58. The data processing device 12 may be a server device, and may be a terminal device owned by the user (for example, a mobile phone, a robot, a home electrical appliance, or the like). Next, description follows regarding an example of processing by the data processing system 10 according to the first exemplary embodiment.

### Example 1

Description follows regarding a flow of the specific processing in an Example 1. The units of the system described below are implemented by the data processing device 12 and the smart device 14. The data processing device 12 is called a “server” and the smart device 14 is called a “terminal”.

Conventional user interface design support tools primarily focus on static previews, heuristic checklists, or basic analytics dashboards. Such tools typically require a human expert to manually interpret logs, apply separate statistical models, or run time-consuming experiments (such as A/B tests) in order to estimate how a proposed design change will affect user behavior and business performance. As a result, prediction of numerical effects of design changes is slow, labor-intensive, and often unavailable during the design phase, when decisions need to be made iteratively and in near real time.

In addition, although recent generative artificial intelligence models are capable of producing rich textual analyses and predictions based on natural language prompts, existing systems generally treat these models as isolated services. In these systems, a human operator must manually craft prompts, manually paste or upload design-related data, and manually extract and post-process the model's textual output. This manual handling introduces variability, reduces reproducibility, and prevents seamless integration of generative artificial intelligence models into a structured design workflow.

Furthermore, when generative artificial intelligence models return prediction results, those results are commonly presented as unstructured text. Such unstructured outputs are difficult for computer systems to interpret as machine-readable data, to normalize into consistent metrics, or to correlate with specific design changes over time. Consequently, known systems are not well-suited for building a time-series history of design decisions and their predicted quantitative effects, or for performing iterative optimization guided by structured, comparable metrics.

Moreover, existing technologies for qualitative user research, such as user interviews and usability testing, require substantial human effort, scheduling, and cost. While generative artificial intelligence models can simulate user feedback, current solutions typically provide ad hoc qualitative narratives without systematic linkage to quantitative predictions or without a unified mechanism for generating interview scenarios and parsing the responses into structured qualitative evaluation information.

Accordingly, there is a need for an improved computer-implemented system that: (i) automatically converts concrete design changes, screen configurations, and user attributes into well-structured prompt sentences suitable for generative artificial intelligence models; (ii) automatically receives, parses, and normalizes prediction results into machine-readable quantitative metrics; (iii) generates and maintains time-series quantitative report information tied to specific design changes; and (iv) systematically produces and analyzes simulated qualitative interviews in a way that is integrated with the quantitative evaluation. Such a system should improve the functioning of the computer itself by enabling automated prompt generation, structured result extraction, and presentation control logic that together allow real-time, data-driven design iteration without manual prompt engineering or manual result parsing.

The specific processing by the specific processing unit 290 of the data processing device 12 in Example 1 is realized by the following means.

The present invention provides a server comprising a processor configured to receive, from a client terminal via a communication network, screen configuration information and operation information representing user manipulations of a design interface, and to generate, based on the received information, design change information that abstractly represents display elements and layout elements of an information processing screen. The processor is further configured to automatically construct, based on the design change information and user attribute information, a prompt sentence in a natural language including a predetermined sentence structure and output format specification, the prompt sentence being configured to cause a generative artificial intelligence model to execute a prediction of quantitative evaluation values including behavior indicators and performance indicators. The processor is also configured to transmit the prompt sentence to the generative artificial intelligence model via the communication network, to acquire from the generative artificial intelligence model a prediction result including the quantitative evaluation values, to extract and normalize the quantitative evaluation values as evaluation data associated with the design change information, and to generate quantitative report information and explanatory text information based on the evaluation data. The processor is further configured to output presentation control information to cause the client terminal to display the quantitative report information and the explanatory text information in a time-series traceable form, and, in certain embodiments, to generate interview setting information, construct additional prompt sentences to cause the generative artificial intelligence model to execute simulated qualitative interviews, analyze qualitative response information, and present qualitative evaluation information in association with the quantitative report information. This enables the computer system to automatically transform low-level design operations into structured prompt sentences, to automatically convert unstructured prediction outputs from the generative artificial intelligence model into machine-readable internal data structures, and to provide integrated quantitative and qualitative evaluation of design changes in real time, thereby improving the efficiency, accuracy, and technical capabilities of computer-assisted user interface design and optimization.

The term “screen configuration information” refers to data representing a structure and arrangement of display elements and layout elements of an information processing screen to be presented on a display device.

The term “operation information” refers to data representing user operations performed on a design interface, including selections, edits, and manipulations applied to display elements and layout elements.

The term “design change information” refers to data that abstractly represents differences between a first design state and a second design state of an information processing screen, including changes to display elements, layout elements, and associated attributes.

The term “display element” refers to a visual component of an information processing screen, such as a control, a text region, an image region, or an interactive component, that is presented to a user via a display device.

The term “layout element” refers to positional and structural information that defines spatial arrangement, ordering, or grouping of display elements on an information processing screen.

The term “user attribute information” refers to data describing characteristics of a user or a group of users, including demographic attributes, device usage attributes, behavioral attributes, or segmentation attributes.

The term “prompt sentence” refers to a sequence of natural language expressions that is constructed according to a predetermined sentence structure and that instructs a generative artificial intelligence model to perform a specified processing, such as prediction, explanation, or simulation.

The term “generative artificial intelligence model” refers to a computational model, implemented by software executed on hardware resources, that generates new data or predictions in response to input information, using machine learning or statistical inference techniques.

The term “quantitative evaluation values” refers to numerical values representing predicted or measured user behavior indicators or performance indicators related to an information processing screen or a design change.

The term “behavior indicators” refers to metrics that quantify user actions or interactions with an information processing screen, such as click-through rate, selection frequency, or navigation path characteristics.

The term “performance indicators” refers to metrics that quantify outcomes or results associated with use of an information processing screen, such as conversion rate, completion rate, error rate, or time required to complete a task.

The term “prediction result” refers to output information generated by a generative artificial intelligence model in response to a prompt sentence, the output information including at least one quantitative evaluation value and optionally explanatory information.

The term “evaluation data” refers to normalized data obtained by processing quantitative evaluation values extracted from a prediction result so as to be associated with corresponding design change information.

The term “quantitative report information” refers to structured information that summarizes one or more quantitative evaluation values associated with a design change and that is suitable for presentation to a user as a quantitative assessment.

The term “explanatory text information” refers to natural language text that explains, interprets, or supplements quantitative report information so as to aid user understanding.

The term “presentation control information” refers to data or instructions used by a client terminal to determine how, when, or in what format quantitative report information and explanatory text information are displayed on a display device.

The term “time-series traceable form” refers to a presentation format in which quantitative report information and explanatory text information are organized or recorded such that changes over time or across multiple design iterations can be visually or logically followed.

The term “interview setting information” refers to data defining conditions for a simulated qualitative interview, including user types, usage situations, roles, or scenarios to be assumed by a generative artificial intelligence model.

The term “user type” refers to a classification of a user based on at least one characteristic, such as experience level, demographic attribute, or device usage pattern.

The term “usage situation” refers to a context or scenario in which a user interacts with an information processing screen, including environmental conditions, task objectives, or device conditions.

The term “simulated qualitative interview” refers to a process in which a generative artificial intelligence model generates text that imitates responses of one or more hypothetical users to a design, according to interview setting information.

The term “qualitative response information” refers to textual data generated by a generative artificial intelligence model in response to a prompt sentence for a simulated qualitative interview, the textual data expressing opinions, feelings, or subjective evaluations.

The term “qualitative evaluation information” refers to structured or organized information derived from qualitative response information and associated with quantitative report information to provide contextual understanding of a design change.

The term “expression format of the prediction result” refers to a representation form in which a prediction result is provided by a generative artificial intelligence model, including at least one of a structured format, a semi-structured format, or an unstructured natural language format.

The term “extraction conditions” refers to rules or parameters used to identify and obtain predetermined indicator values and explanatory elements from a prediction result.

The term “machine-readable internal data structure” refers to a data representation, such as an object, a record, or a data structure in memory, that is generated by a processor from a prediction result and that can be programmatically processed without natural language interpretation.

The term “presentation content” refers to information that is output to a display device or another user interface element for viewing or perception by a user, including text, graphics, charts, or combined visual elements.

In one embodiment, the system includes a server, a terminal, and a communication network connecting the server and the terminal. The server includes at least one processor, a memory, a non-transitory storage medium, and a network interface. The terminal includes at least one processor, a display device, an input device such as a pointing device or a touch-sensitive panel, and a network interface. The server and the terminal execute software modules that cooperate to generate prompt sentences for a generative AI model, to obtain prediction results, and to present quantitative and qualitative evaluations of design changes.

The terminal executes a web application implemented, for example, by HTML, Cascading Style Sheets, and JavaScript. The terminal may use a client-side framework such as a component-based JavaScript framework executing in a web browser. The terminal presents a design editing interface that displays an information processing screen preview and property panels. The terminal receives user operations, such as selection of a button element, modification of color values via a color picker widget, editing of label text via a text input field, and adjustment of layout positions via drag-and-drop operations.

The terminal converts the user operations into operation information represented as structured data in a client-side data model. The terminal stores, in a local memory, screen configuration information that represents current display elements, their attributes, and layout elements such as positions, groupings, and ordering. The terminal updates the screen configuration information in response to the user operations and presents an updated preview using a rendering engine of the web browser.

The terminal transmits the screen configuration information and the operation information to the server via the communication network using a request-response protocol such as HTTP over Transport Layer Security. The terminal serializes the data into a structured format and attaches metadata such as a project identifier, a user identifier, and a timestamp. The terminal performs this transmission using a network library such as a browser-provided fetch interface or an asynchronous HTTP client library.

The server stores, in the memory and the non-transitory storage medium, one or more software modules, including a data ingestion module, a design change abstraction module, a prompt generation module, a generative AI interface module, a prediction parsing module, a report generation module, and a presentation control module. The server further stores configuration data defining prompt templates, output format specifications, and extraction rules for interpreting prediction results.

The server uses the data ingestion module to receive and parse incoming requests from the terminal. The server converts the serialized screen configuration information and operation information into internal data structures, such as objects or records, and validates data formats. The server normalizes color codes, layout coordinates, and textual labels into a canonical representation so that differences between design states can be computed efficiently.

The server uses the design change abstraction module to compute design change information. The server compares a previous design state stored in a design history repository with a current design state represented by the received screen configuration information. The server identifies modified display elements by comparing unique element identifiers and attribute values. The server computes, for each modified element, a change vector that includes differences in color values, text content, size, position, and other visual or interactive attributes. The server aggregates these change vectors into design change information that abstractly represents what has changed between the previous and current screen states.

The server stores the design change information in association with a design version identifier in the non-transitory storage medium. The server additionally associates the design change information with user attribute information retrieved from a user profile database. The user attribute information includes, for example, demographic segments, device types, and behavioral segments that are relevant for prediction.

The server uses the prompt generation module to construct a prompt sentence for a generative AI model. The server reads a prompt template from the configuration data, where the template specifies a sentence structure and an output format specification. The template may define parameter placeholders for element type, page type, old state, new state, target user segment, and required metrics. The server populates these placeholders using values extracted from the design change information and the user attribute information.

For example, the server generates a prompt sentence such as: “Please predict the impact on user behavior when the primary call-to-action button on the checkout page is changed from blue (#0000FF) with label ‘Buy Now’ to red (#FF0000) with label ‘Get Started Now’. Provide numerical estimates for click-through rate, conversion rate, and bounce rate, and briefly explain the reasons. Return the result in JSON-like form with keys ctr_change, conversion_change, and bounce_change.”

In another example, the server generates a prompt sentence such as: “Please predict the impact on user behavior (click-through rate, conversion rate, bounce rate) if the main ‘Buy Now’ button color is changed from blue (#0000FF) to red (#FF0000) on the product detail page for mobile users in their 20s. Provide the predicted percentage change for each metric and a short explanation.”

The server can generate different types of prompt sentences according to configuration. For quantitative prediction, the server emphasizes numeric outputs and explicit key names; for qualitative simulation, the server emphasizes persona descriptions and narrative content. The server encodes explicit output format constraints in the prompt sentence, such as requesting a key-value list or a fixed label for each metric. By applying these non-conventional prompt constraints, the server reduces ambiguity in the model output and improves machine parsing accuracy.

The server uses the generative AI interface module to transmit the prompt sentence to a generative AI model. The server may communicate with an external inference service over the communication network or with a locally hosted model via an internal network. The server constructs a request payload containing the prompt sentence and model parameters such as maximum token count, sampling temperature, and top-k or top-p values. The server sends the payload using a network library such as a generic HTTP client or a specialized model access library.

In one embodiment, the generative AI model is implemented as a transformer-based neural network comprising multiple attention layers, feed-forward sublayers, and layer normalization units. The model includes an embedding layer that converts tokenized words from the prompt sentence into vector representations, multiple stacked self-attention blocks that compute attention scores over the token sequence, and a final projection layer that maps internal states to probabilities over output tokens. The model parameters, including weight matrices and bias vectors, are stored on one or more processing units such as graphics processing units or tensor processing units.

The generative AI model is previously trained on a corpus containing user interaction data, interface descriptions, and behavior metrics. During training, the server or another training system uses supervised fine-tuning with labeled examples of design changes and observed metric changes. The system defines a loss function that combines a language modeling loss with a regression loss on quantitative metrics. The regression loss measures the squared error between predicted metric deltas and ground-truth metric deltas. The training system updates model parameters using a gradient-based optimization method such as stochastic gradient descent with adaptive moment estimation. The training system can apply data augmentation by generating variant descriptions of the same design change to make the model robust to different expressions.

When the server transmits the prompt sentence, the generative AI model performs inference. The model tokenizes the input, applies the trained neural network layers, and outputs a sequence of tokens representing a structured or semi-structured prediction result. Because the prompt sentence explicitly requests given keys and formats, the model tends to output a text that includes the requested key labels and numeric values in a predictable order.

The server uses the prediction parsing module to interpret the prediction result. The server first detects whether the result conforms to a structured pattern by applying pattern-matching rules or parsing logic configured for the requested format. For example, the server searches for substrings following the labels “ctr_change”, “conversion_change”, and “bounce_change” and extracts numeric values. The server converts percentages into fractional values when necessary. The server normalizes these values into an internal numeric type. When the prediction result is less structured, the server uses extraction conditions, such as regular expressions and delimiter-based scanning, to locate values adjacent to known metric names. The server generates evaluation data by associating the extracted quantitative evaluation values with the corresponding design change information and user attribute information. The server stores the evaluation data in a time-series database or another structured storage. The server uses an internal data structure that includes fields for design version identifiers, timestamps, metric identifiers, metric values, and confidence indicators. The server maintains an index over these fields to support efficient retrieval and aggregation over multiple design iterations.

The server uses the report generation module to create quantitative report information. The server converts the metric values into human-understandable formats such as percentage increases or decreases. The server groups metrics into logical categories such as behavior indicators and performance indicators. The server compiles the information into a report structure that may include summaries, detailed values, and comparison to baseline values. The server also constructs explanatory text information. The server may reuse causality or rationale sentences included in the prediction result or may generate additional explanatory sentences by applying template-based language generation. For instance, the server can produce a text such as:

“Estimated impact: click-through rate +6%, conversion rate +3%, bounce rate −1%. Reason: The new red button with an action-oriented label is more visually salient and motivating, which encourages more users to click and complete the checkout process.”

The server uses the presentation control module to generate presentation control information. This information defines visual layouts, chart types, color coding rules, and timeline arrangements for displaying the quantitative report information and explanatory text information. The server encodes, for example, which metrics to show as bar charts, which to show as line graphs over iterations, and which to highlight as warnings. The server also defines rules for ordering design iterations in a time-series manner and for switching between versions.

The server transmits the presentation control information, together with the quantitative report information and explanatory text information, to the terminal using the communication network. The terminal receives this data and renders a report interface. The terminal uses its graphics rendering engine to draw tables, graphs, and explanatory texts. The terminal allows the user to select previous design versions and to compare predicted metrics across versions. The terminal thereby enables the user to visually trace the evolution of predictions over time.

In one embodiment, the server generates additional prompt sentences to conduct simulated qualitative interviews. The server constructs interview setting information by selecting user types and usage situations based on the design change information and the quantitative evaluation values. For example, the server may define a persona set including a novice user on a mobile device, an expert user on a desktop device, and a time-constrained user. The server generates a prompt sentence such as: “Act as three different users: (1) a novice user on a smartphone, (2) an experienced user on a desktop computer, and (3) a busy user in a hurry. Each user is viewing an e-commerce checkout page where the primary call-to-action button has changed from blue (#0000FF) with label ‘Buy Now’ to red (#FF 0000) with label ‘Get Started Now’. For each user, describe in 3-4 sentences how this change affects trust, motivation, and likelihood to click.”

The server sends this prompt sentence to the generative AI model. The model produces qualitative response information imitating each persona. The server analyzes the qualitative response information by applying natural language processing routines such as keyword extraction, sentiment scoring, and topic clustering. The server groups sentences into positive, neutral, and negative categories and identifies recurring concerns or advantages. The server converts the analysis into qualitative evaluation information, such as “perceived urgency increased,” “trust slightly decreased for cautious users,” or “clarity of action improved.” The server associates this qualitative evaluation information with the quantitative report information in the report data structure. The terminal presents the qualitative evaluation information as textual summaries or annotated comments alongside charts, enabling the user to see how different user types may respond to the design change.

The server improves computer technology in several ways. First, the server defines a non-conventional data flow that transforms low-level screen configuration information and operation information into abstract design change information, and then into structured prompt sentences for a generative AI model, and then into normalized evaluation data and presentation control information. This transformation pipeline allows the server to reuse a single generative AI model for multiple types of analysis (quantitative predictions and qualitative interviews) without manual prompt engineering. The explicit prompt structure and output format specification reduce variability in model outputs and allow automated parsing with reduced error rates. As a result, the server performs machine interpretation of model outputs in a way that cannot be achieved by simply substituting a human operator.

Second, the server uses specific extraction conditions and internal data structures to convert unstructured natural language results into machine-readable internal data. This improves data management and enables efficient indexing, aggregation, and time-series comparison of predicted metrics. By storing evaluation data linked to design versions, the server allows rapid retrieval of historical predictions and supports complex queries such as “show all design changes that improved conversion rate above a threshold.” This database-oriented design enhances computational efficiency and reduces communication load, because only compact evaluation data needs to be repeatedly transferred between the server and the terminal, rather than full raw model outputs.

Third, the server leverages a transformer-based generative AI model that has been fine-tuned with a specialized loss function combining linguistic and numerical prediction tasks. This training approach reduces numerical prediction error and stabilizes the relationship between textual descriptions and predicted metrics. The server's use of output format constraints in prompt sentences further reduces post-processing time. The combination of training configuration and prompt structure produces higher-precision predictions per inference step compared to generic language models, thus improving the technical performance of the prediction subsystem.

Fourth, the server introduces rule-based prompt construction and rule-based parsing strategies that differ from conventional manual operations. The server systematically encodes metric identifiers, unit formats, and persona variables into prompt sentences using deterministic algorithms. Likewise, the server uses configuration-driven extraction conditions tuned to the requested output format. This dual-rule system allows the server to adapt to different model output formats by switching extraction conditions without changing core logic, and it reduces parsing errors even when the generative AI model exhibits minor variations in wording. Therefore, the system improves robustness and reduces the need for repeated network calls or manual corrections, yielding improved processing speed and reduced computational load.

Fifth, the server and the terminal together implement a feedback loop that is tightly integrated into interface rendering and data storage mechanisms. When the terminal sends incremental design changes, the server can reuse previous baseline data and only compute deltas for modified elements, thus reducing redundant computation. The server can also schedule multiple prediction requests for queued design changes and merge the results into batch responses. These design choices reduce network traffic and allow the system to provide near real-time predictions despite limited computational resources.

In alternative embodiments, the server may host the generative AI model locally, in which case the server loads the model weights into memory and performs inference without involving an external service. The server may distribute model inference across multiple processors or accelerators and use model sharding techniques. In such embodiments, the server can further optimize processing by dynamically adjusting model parameters such as sequence length, precision type, or batch size. The server can reduce inference latency by selecting a lighter model variant for rapid feedback during early design exploration and a heavier, more accurate model variant for final evaluations.

In another embodiment, the terminal may be a mobile computing device executing a native application. The terminal may pre-process screen configuration information using device-specific layout constraints and may adapt presentation control information to fit smaller displays. The server may adjust prompt sentences and interview setting information to consider device-specific behavior patterns, such as thumb reachability or limited input precision, thereby generating predictions tailored to mobile contexts.

In yet another embodiment, the server may support multiple generative AI models and select among them based on use case. For example, the server may route purely quantitative prediction tasks to a regression-oriented neural network model without natural language output, and route qualitative interview tasks to a language-oriented transformer model. The server may combine outputs from both models in the report generation module. This modular architecture allows the system to improve overall throughput and to match model capacities to requested analysis types.

Because the server executes these specialized data transformations, prompt generation strategies, structured parsing, and time-series data management, the system provides technical effects such as faster prediction generation, reduced parsing errors, improved consistency of model outputs, and efficient storage and retrieval of evaluation data. The server reduces human intervention in steps that are not merely clerical automation but involve configuration-driven mapping between internal data structures and generative AI interfaces. The resulting improvements in processing speed, accuracy, and robustness constitute enhancements to the operation of the computer system itself and enable applications in interface optimization that were not feasible with conventional, manually managed generative AI usage.

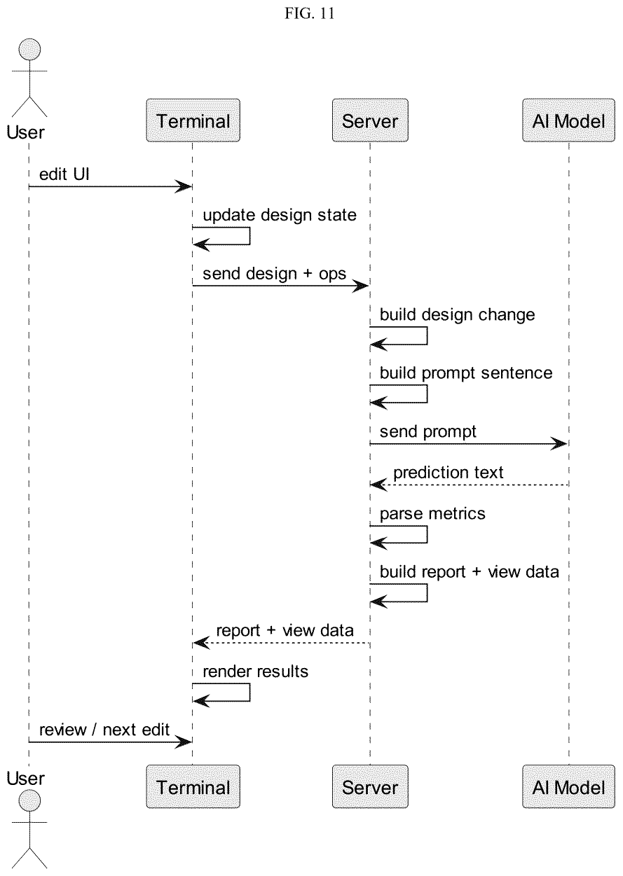

The following describes the processing flow using FIG. 11.

### Step 1

The user operates the terminal to edit a design on a displayed interface.

The user selects display elements such as buttons, input fields, or images on a preview screen and modifies properties like color, text, size, and position using input controls including color pickers, text boxes, and drag-and-drop operations.

The input to this step is the existing design state displayed on the terminal and user manipulation events (clicks, touches, drags, keyboard entries). The output of this step is operation information held in the terminal's internal data model, representing which elements were modified and how their attributes changed.

### Step 2

The terminal generates screen configuration information and updates its local representation of the design.

The terminal takes the operation information as input and applies the changes to an in-memory structure describing the current screen, including a list of display elements, their attributes (such as color codes and text strings), and layout elements (such as coordinates and z-order). The terminal performs data processing by updating attribute values, recalculating layout positions if necessary, and re-rendering the screen using the browser's rendering engine.

The input to this step is the operation information describing user edits. The output is updated screen configuration information and an updated visual preview on the terminal's display.

### Step 3

The terminal transmits screen configuration information and operation information to the server.

The terminal serializes the updated screen configuration information and the operation information into a structured payload, attaches metadata including a project identifier, a user identifier, and a timestamp, and sends this payload to the server via a communication network using a secure protocol. The terminal uses a network interface and an HTTP client implementation to perform the transmission.

The input to this step is the updated screen configuration information and operation information in the terminal's memory. The output is a network request message received by the server containing serialized design-related data.

### Step 4

The server receives and parses the design-related data from the terminal.

The server accepts the incoming request through a network interface, reads the serialized payload, and converts it into internal data structures using a data ingestion module. The server validates required fields, checks data types (for example, color strings and coordinate values), and discards or logs inconsistent records. The server maintains references linking the received data to existing projects and users.

The input to this step is the network request message from the terminal. The output is normalized internal objects representing screen configuration information and operation information stored in the server's memory.

### Step 5

The server computes design change information by comparing current and previous design states.

The server retrieves a previous design state associated with the same project identifier from persistent storage and compares it with the current screen configuration information. The server performs data processing by aligning elements via identifiers, detecting additions, deletions, and modifications, and forming change vectors that record differences in properties such as color, text, size, and position. The server aggregates these change vectors into design change information representing the abstracted modifications between two design versions.

The input to this step is the current screen configuration information and the previous design state retrieved from storage. The output is design change information stored as an internal data structure linked to the design history.

### Step 6

The server associates user attribute information with the design change information.

The server retrieves user attribute information from a user profile database based on the user identifier or specified target segments. The server merges the user attribute information with the design change information by attaching segment labels such as demographic group, device type, and behavior category. The server thus prepares a combined context for prediction.

The input to this step is the design change information and user attribute records from storage. The output is enriched design change information including attributes of target user segments.

### Step 7

The server generates a prompt sentence to request quantitative prediction from a generative AI model.

The server selects a prompt template from configuration data according to the type of design change and the metrics to be predicted. The server fills placeholders in the template using values from the enriched design change information, such as element type, page type, old state, new state, and target segment. The server performs string concatenation and formatting operations to create a coherent natural language prompt sentence that includes explicit instructions about desired metrics and output format.

The input to this step is the enriched design change information and the selected prompt template. The output is a prompt sentence such as:

“Please predict the impact on user behavior when the primary call-to-action button on the checkout page is changed from blue (#0000FF) with label ‘Buy Now’ to red (#FF0000) with label ‘Get Started Now’. Provide numerical estimates for click-through rate, conversion rate, and bounce rate, and briefly explain the reasons. Return the result in JSON-like form with keys ctr_change, conversion_change, and bounce_change.”

### Step 8

The server transmits the prompt sentence to the generative AI model and initiates inference.

The server constructs a model request payload containing the prompt sentence and parameters such as maximum output length and sampling temperature. The server uses a generative AI interface module to send this payload to the generative AI model, either via an external API over the network or via an internal interface to a locally hosted model. The server records a correlation identifier to track the request.

The input to this step is the prompt sentence and model configuration parameters. The output is an inference request delivered to the generative AI model and a pending state on the server awaiting a prediction result.

### Step 9

The generative AI model generates a prediction result in response to the prompt sentence.

The generative AI model receives the prompt sentence, tokenizes it into discrete units, and applies a trained neural network architecture including multiple attention layers and feed-forward layers. The model processes the token sequence to generate output tokens that encode numeric predictions for requested metrics and explanatory text, following the output format instructions in the prompt sentence.

The input to this step is the prompt sentence tokens and internal model parameters (weights and biases). The output is a prediction result expressed as a text sequence that includes values for behavior indicators and performance indicators along with explanatory language.

### Step 10

The server receives and parses the prediction result from the generative AI model.

The server obtains the text sequence returned by the generative AI model through the generative AI interface module. The server applies parsing logic based on configured extraction conditions, such as locating labels “ctr_change”, “conversion_change”, and “bounce_change” and extracting adjacent numeric values. The server converts these numeric values into a normalized internal representation (for example, floating-point values) and separates the remaining explanatory sentences.

The input to this step is the prediction result text from the generative AI model. The output is normalized quantitative evaluation values and explanatory text stored in internal data structures.

### Step 11

The server generates evaluation data and quantitative report information.

The server associates the normalized quantitative evaluation values with the design change information and user attribute information, forming evaluation data entries that include design version identifiers, metric identifiers, and metric values. The server writes these entries into a time-series storage structure. The server then computes human-readable representations such as percentage changes and baseline comparisons, and assembles them into quantitative report information. The server also processes the explanatory text to create explanatory text information that summarizes main reasons and effects.

The input to this step is the normalized quantitative evaluation values, explanatory text, and design change information. The output is evaluation data records and a structured quantitative report with associated explanatory text information.

### Step 12

The server generates presentation control information for the terminal.

The server determines which metrics to highlight, which visualization types to use, and how to order design iterations in a timeline. The server encodes layout instructions, chart configurations, and label texts as presentation control information. The server performs data processing by mapping numeric ranges to visual styles (such as colors or icons) and formatting values for display.

The input to this step is the quantitative report information, explanatory text information, and system configuration rules for presentation. The output is presentation control information that specifies how the terminal should display the report content.

### Step 13

The server transmits the quantitative report information, explanatory text information, and presentation control information to the terminal.

The server packages these data into a response payload and sends it to the terminal over the communication network using a response protocol. The server may compress the payload or omit raw model output to reduce network usage, thereby sending only normalized and structured data.

The input to this step is the generated report and presentation control information stored in the server's memory. The output is a response message delivered to the terminal containing all information required for user presentation.

### Step 14

The terminal receives the response and renders a prediction and evaluation view.

The terminal parses the response payload and updates its internal state, mapping presentation control information to UI components. The terminal renders charts, tables, and texts that show predicted changes in behavior indicators and performance indicators, and arranges them according to the prescribed time-series layout. The terminal may highlight the current design iteration and display previous iterations for comparison.

The input to this step is the response message from the server containing quantitative report information, explanatory text information, and presentation control information. The output is an updated display on the terminal showing numerical predictions, explanations, and historical context.

### Step 15

The user reviews the displayed predictions and decides on further design actions.

The user examines numerical values such as predicted click-through rate change, conversion rate change, and bounce rate change, as well as the explanatory text describing expected user reactions. The user may choose to accept the design change, revert it, or apply additional modifications using the design editing interface.

The input to this step is the visualized report and explanatory content on the terminal's display. The output is a new sequence of user operations, which may trigger another cycle of steps starting from design editing.

### Step 16

The server optionally generates a prompt sentence for a simulated qualitative interview and processes its result.

The server uses the same or additional design change information and quantitative evaluation values as input to construct interview setting information indicating multiple user types and usage situations. The server generates a prompt sentence instructing the generative AI model to assume specific personas and to describe subjective reactions. The server sends this prompt sentence to the generative AI model, receives qualitative response information, and analyzes the responses to extract recurring concerns, sentiments, or themes. The server then creates qualitative evaluation information linked to the quantitative report.

The input to this step is design change information, quantitative evaluation values, and interview setting rules. The output is qualitative evaluation information derived from the generative AI model's response, which can be subsequently transmitted to the terminal for display alongside quantitative metrics.

### Application Example 1

Description follows regarding a flow of the specific processing in an Application Example 1. The units of the system described below are implemented by the data processing device 12 and the smart device 14. The data processing device 12 is called a “server” and the smart device 14 is called a “terminal”.

In the field of computer-implemented user interface design, it is difficult for conventional systems to provide immediate and reliable predictions of how specific design changes to a digital presentation, such as an electronic commerce product page, will affect user behavior and business performance indicators. Traditional approaches typically rely on manual heuristic evaluations, offline usability testing, or delayed analysis of A/B test results. These approaches require significant human effort, depend heavily on designer intuition, and incur substantial latency between implementing a design change and understanding its quantitative impact. As a result, designers and administrators are often unable to iteratively optimize user interfaces in real time based on objective metrics.

Furthermore, conventional systems that employ machine learning prediction models are generally limited to numerical inference pipelines that treat the prediction task as a black box. Such systems do not integrate the numerical prediction pipeline with a natural language generation pipeline capable of producing rich qualitative insights or concrete improvement proposals tailored to diverse user attributes and usage contexts. Consequently, users of these systems receive raw numerical outputs that are difficult to interpret without specialized analytical skills, and they lack an automated mechanism to obtain alternative design suggestions or simulated qualitative feedback.

In addition, in existing architectures, the interaction between client devices and server-side prediction components is typically one-directional and coarse-grained. Client devices submit design data, the server returns a static prediction, and any subsequent refinement requires manual reconfiguration of the model input and independent analysis. There is no integrated computer-implemented framework that unifies: (i) the acquisition and association of change history data and user behavior data; (ii) systematic preprocessing into feature data for numerical computation; (iii) generation of structured prompt sentences for a generative artificial intelligence model; and (iv) closed-loop, real-time iteration that transforms successive user design edits into progressively optimized interface configurations. This fragmentation limits the ability of computer systems to efficiently support iterative design workflows.

From the viewpoint of computer technology, there is a need for an improved server-side processing architecture that coordinates a trained numerical prediction model and a generative artificial intelligence model by way of explicit prompt sentences and structured feature data, thereby enhancing the functioning of the computer system itself. More specifically, there is a need for a system that can automatically: (a) generate appropriate machine-readable and human-readable representations of design changes, (b) perform optimized data retrieval and feature preprocessing for predictive computation, (c) couple numerical predictions with language-based qualitative explanations, and (d) drive a feedback loop that supports real-time, interactive design optimization without requiring manual scripting or ad hoc integration work each time the interface is modified.

Therefore, an object of the present invention is to provide a computer-implemented system and techniques that improve the operation of servers and client devices in performing design evaluation and optimization, by integrating numerical prediction, prompt-based generative artificial intelligence processing, and iterative feedback control into a unified, technically enhanced workflow.

The specific processing by the specific processing unit 290 of the data processing device 12 in Application Example 1 is realized by the following means.

The present invention provides a server comprising a processor configured to receive, from a terminal device, design change information including a plurality of presentation elements of a display and corresponding change contents, to acquire, from a storage device, past change history information and behavior history information and associate them as learning input information, to perform preprocessing on the learning input information to generate feature data for numerical computation, to input the feature data into a trained prediction model executed on a numerical computation device to calculate predicted values of indicators including click-through rate, conversion rate, and revenue-related indicators, to generate, based on the feature data, the design change information, and the predicted values, a prompt sentence for input into a generative artificial intelligence model, to cause the generative artificial intelligence model to generate a natural language response including qualitative insights and improvement proposals regarding an influence of the design change on user behavior and business indicators, to analyze the predicted values and the natural language response to generate feedback information including quantitative evaluation information and a plurality of improvement options, to format and transmit the feedback information to the terminal device for presentation to an administrator, and to receive, from the terminal device, new design change information and iterative evaluation requests and rerun the numerical prediction processing and processing using the generative artificial intelligence model to support real-time optimization of the design. This enables the computer system to more efficiently utilize historical data and predictive models, to automatically construct and apply structured prompt sentences for generative artificial intelligence processing, to integrate numerical and qualitative outputs in a machine-controlled feedback loop, and thereby to improve the technical performance of the server and terminal device in executing real-time, iterative user interface optimization tasks.

The term “processor” refers to a hardware or virtual computing component, such as a central processing unit or a processing core, configured to execute instructions of computer programs to perform the functions described in the present specification.

The term “terminal device” refers to an information processing apparatus operated by a user or administrator, such as a client computer, mobile communication device, or other user interface device, that transmits design change information to the server and receives feedback information from the server.

The term “design change information” refers to data representing a modification to one or more elements of a digital presentation, including identification of a target display or page, identification of one or more presentation elements, and values indicating a change of appearance, layout, content, or behavior of the elements.

The term “presentation element” refers to a component of a graphical user interface or digital display, including but not limited to a background region, text region, image region, interactive control, or layout container, that is visually or functionally exposed to a user.

The term “change contents” refers to data indicating how a presentation element is to be modified, including, for example, a change of color, size, position, font property, image property, or other display or interaction parameter.

The term “storage device” refers to any non-transitory computer-readable medium, such as a magnetic storage apparatus, optical storage apparatus, semiconductor memory, or distributed storage system, that stores past change history information, behavior history information, model parameters, or other data used by the processor.

The term “past change history information” refers to stored data indicating previous modifications applied to presentation elements of digital presentations, including identifiers of the elements, before-change values, after-change values, timestamps, and contextual information of the modifications.

The term “behavior history information” refers to stored data representing user behavior in response to digital presentations, including, for example, access logs, click events, scrolling events, purchase events, conversion events, dwell times, and associated contextual attributes.

The term “learning input information” refers to data constructed by associating past change history information with behavior history information, formatted as input for a prediction model or other machine learning component.

The term “preprocessing” refers to computational operations performed on learning input information prior to prediction, including at least one of cleaning, quantization, normalization, encoding of categorical values, feature extraction, and transformation into numerical feature data suitable for numerical computation.

The term “feature data” refers to numerical data derived from preprocessing of learning input information, formatted as one or more vectors, matrices, or tensors, and used as input to a prediction model or other numerical computation component.

The term “numerical computation device” refers to a computing resource configured to execute numerical operations on feature data, such as a central processing unit, graphics processing unit, tensor processing unit, or other hardware accelerator.

The term “trained prediction model” refers to a machine learning or statistical model whose parameters have been adjusted using training data, and which is configured to receive feature data and output predicted values of one or more indicators.

The term “indicator” refers to a numerical metric representing system performance or user behavior, including but not limited to click-through rate, conversion rate, revenue per unit time, revenue per session, and other business-related or engagement-related metrics.

The term “generative artificial intelligence model” refers to a machine learning model configured to generate output data, such as natural language text, in response to input data including a prompt sentence and optionally structured numerical data, based on learned patterns from training data.

The term “prompt sentence” refers to a sequence of natural language tokens or structured textual content prepared for input to a generative artificial intelligence model, describing at least a design change, contextual information, and optionally predicted values of indicators, to condition the generation of a response.

The term “natural language response” refers to one or more sequences of human-readable text generated by the generative artificial intelligence model in response to a prompt sentence and optionally additional data.

The term “qualitative insights” refers to non-numerical explanatory information expressed in natural language that describes possible user perceptions, motivations, or reactions to a design change, and interprets or contextualizes numerical prediction results.

The term “improvement proposals” refers to design recommendations expressed as natural language instructions or structured data that specify one or more modifications to presentation elements or configurations intended to improve indicators.

The term “feedback information” refers to data generated by the processor that includes at least quantitative evaluation information based on predicted values of indicators and qualitative information including natural language explanations, recommendations, or improvement proposals.

The term “quantitative evaluation information” refers to numerical or machine-readable values that express an estimated effect of a design change on one or more indicators, including predicted values, differences from baseline values, and statistical measures.

The term “improvement option” refers to one candidate design configuration or change pattern among a plurality of proposed design modifications, each intended to improve at least one indicator relative to a reference configuration.

The term “data structure” refers to an organized format for storing and transmitting data, such as a record, object, array, or document structure, including but not limited to a structure conforming to a markup or serialization format.

The term “administrator” refers to a human operator who uses the terminal device to configure or evaluate design changes of a digital presentation and to interpret the feedback information provided by the server.

The term “iterative evaluation request” refers to a request transmitted from the terminal device to the server to perform further prediction and analysis in response to updated design change information or prior feedback information, thereby enabling repeated evaluation cycles.

The term “real-time optimization of the design” refers to a computer-implemented process in which design changes are repeatedly evaluated and refined within short response times, such that updated prediction results and feedback can be provided during an ongoing design session.

The term “user attribute” refers to any characteristic associated with a user or user group, including, for example, demographic information, device type, usage frequency, purchase history, or other classification information.

The term “usage context” refers to environmental or situational conditions relevant to user interaction, including, for example, access time, access location, access device category, traffic source, or campaign condition.

The term “virtual subject” refers to a simulated user persona or user representative, defined based on user attributes and usage contexts, for which the generative artificial intelligence model generates simulated responses in a virtual interview scenario.

The term “interview scenario” refers to a description, expressed at least partly in natural language, specifying roles of virtual subjects, questions, prompts, or situations used by the generative artificial intelligence model to generate simulated responses regarding a design change.

The term “qualitative evaluation information” refers to information derived from analysis of simulated responses of virtual subjects or other natural language outputs, representing subjective assessments, preferences, or concerns related to a design change.

The term “graph information” refers to data representing graphical depictions of numerical values, such as bar charts, line charts, distribution plots, or other visualizations suitable for display on a terminal device.

The term “summary text information” refers to condensed natural language information that explains, in a concise form, the main points of predicted values, qualitative insights, and recommended design changes.

The term “design change proposal information” refers to structured or semi-structured data representing specific recommended modifications to presentation elements, including, for example, target elements, new parameter values, and expected effects.

In one embodiment, a server implements the claimed system by executing a program on general-purpose or dedicated hardware. The server includes at least one central processing unit, a main memory, a non-transitory storage device, a network interface, and optionally one or more hardware accelerators such as graphics processing units or tensor processing units. The server runs an operating system such as a general-purpose server operating system and an application stack including a web application framework, a data processing library, and a machine learning framework such as a tensor-based numerical computation framework or a dynamic computation graph framework. The server stores model parameters, historical data, and configuration files on a storage device such as a solid-state drive or network-attached storage.

In one embodiment, a terminal is implemented as a client device such as a personal computer, a tablet computer, or a mobile communication device. The terminal executes a browser program or a native application that presents a user interface for editing digital presentations and for visualizing prediction and feedback information. The terminal communicates with the server over a network such as a packet-switched network using a protocol such as an HTTP-based protocol.

In one embodiment, a user operates the terminal to modify presentation elements of a digital page, such as a product page in an electronic commerce system. The user modifies presentation elements by selecting items in a graphical editor, including but not limited to background regions, text fields, image regions, and interactive controls. The terminal converts the modifications into design change information including identifiers of the target page, identifiers of presentation elements, and new values of properties such as color, size, font type, position, and layout structure. The terminal transmits the design change information as a structured request to the server through the network interface.

In one embodiment, the server stores past change history information and behavior history information in a relational database system or a distributed key-value store. The server, upon receiving design change information from the terminal, accesses the storage device through a database management subsystem to retrieve past change history information associated with similar page identifiers, similar presentation elements, and similar value ranges. The server also retrieves behavior history information including click events, viewing durations, conversion events, and revenue-related events associated with those past changes. The server associates these records and constructs learning input information by grouping records according to page identifiers, user segments, and temporal context.

In one embodiment, the server preprocesses the learning input information using a data processing library such as an array-based numerical library. The server encodes categorical data such as color names, font families, layout types, and device types into numerical indices and then into one-hot vectors or learned embedding indices. The server normalizes numerical data such as existing click-through rates, conversion rates, dwell times, and revenue values using techniques such as min-max scaling or z-score normalization. The server organizes these values into feature data represented as multi-dimensional arrays or tensors, where each axis corresponds to a sample, a feature, and optionally a temporal dimension.

In one embodiment, the server implements a trained prediction model as a multi-layer neural network using a machine learning framework. The neural network may include at least one input layer receiving the feature data, a plurality of hidden layers including fully connected layers, activation functions such as rectified linear units or Gaussian error linear units, normalization layers such as batch normalization layers, and regularization layers such as dropout layers. The output layer produces predicted values of indicators such as click-through rate, conversion rate, and revenue-related metrics. In another embodiment, the server implements the trained prediction model as a gradient-boosted decision tree ensemble or a combination of linear and non-linear models.

In one embodiment, the server trains the prediction model offline by using the learning input information and known target indicators from past data. The server defines a loss function such as mean squared error or cross-entropy error between predicted indicators and observed indicators. The server updates model parameters using an optimization algorithm such as stochastic gradient descent with momentum, an adaptive moment estimation method, or another iterative optimization method. The server may perform data augmentation by generating synthetic variations of design changes within plausible ranges and associating them with extrapolated indicator values, thereby improving model robustness and reducing overfitting. The server stores the trained parameters on the storage device and loads them into the main memory and, optionally, into a hardware accelerator at runtime to perform inference.

In one embodiment, the server implements a generative AI model as a language model using a transformer-based architecture. The language model includes an input embedding layer that converts each token of a prompt sentence into an embedding vector, a plurality of self-attention layers that compute attention scores between tokens, feed-forward layers that transform intermediate representations, and a final output layer that produces probability distributions over a vocabulary for each token position. The server trains or fine-tunes the generative AI model on text corpora that include explanations of user behavior, design rationale, and interview-like dialogue. In some embodiments, the server uses an externally provided language model service and transmits tokenized prompt sentences and auxiliary data to that service through an application programming interface.

In one embodiment, the server constructs a prompt sentence by concatenating textual descriptions of the design change, contextual information, and predicted indicator values into a single natural language sequence. For example, the server may construct a prompt sentence as:

“Predict the impact on click-through rate and conversion rate when the background color of the product page is changed from blue to green. Use historical data of similar color changes and explain the reasoning for different user segments on mobile devices and desktop devices.”

In another example, the server may construct a prompt sentence as: “The model predicts that changing the background color from blue to green will increase click-through rate by 5 percent and conversion rate by 2 percent. Based on interface design principles and historical interaction data, explain why users in the age range 20 to 30 on mobile devices might respond positively to this change, and suggest two alternative design variations.”

In still another example, the server may construct a prompt sentence as: “For a product page where the background color is changed from blue (#0000FF) to green (#00AA00), and the main call-to-action button remains orange (#FFA500), predict the impact on click-through rate and conversion rate. Provide three qualitative reasons for the predicted impact for mobile users aged 20 to 30.”

In one embodiment, the server optionally appends structured indicator values to the prompt sentence in textual form, such as: “The current baseline click-through rate is 10 percent and the current baseline conversion rate is 2 percent. The predicted click-through rate after the change is 10.5 percent and the predicted conversion rate after the change is 2.04 percent.”

The server then inputs the prompt sentence as tokenized text into the generative AI model.

The server uses the numerical computation device to compute attention scores, to propagate activations through the layers, and to generate a natural language response containing qualitative insights and improvement proposals.

In one embodiment, the server configures the generative AI model to simulate interview scenarios. The server includes, in the prompt sentence, roles for virtual subjects based on user attributes and usage contexts. For example, the server may generate a prompt sentence as:

“The model predicts: click-through rate plus 3 percent, conversion rate minus 1 percent after increasing the product image size by 30 percent and moving the ‘Buy Now’ button below the fold. Generate interview-style comments from a price-sensitive user, a brand-loyal user, and a first-time visitor that explain these changes in behavior.”

In response, the generative AI model outputs natural language text that mirrors responses by different virtual subjects. The server analyzes the responses by applying natural language processing algorithms, such as keyword extraction, sentiment analysis, or clustering, to identify recurring concerns and preferences. The server converts these results into qualitative evaluation information and aggregates them with quantitative indicator values.

In one embodiment, the server assembles feedback information as a structured record including fields for predicted indicator changes, baselines, confidence intervals, natural language summaries, detailed qualitative insights, and design improvement options. The server may generate auxiliary data for visualization, such as arrays representing time series of predicted performance, distribution of outcomes across user segments, or comparison graphs between different design alternatives. The server transmits the feedback information to the terminal using a structured message format over the network.

In one embodiment, the terminal receives the feedback information and renders it using a graphical user interface framework. The terminal displays numeric values as text and plots graphs using a visualization library. The terminal presents the natural language response as readable text, and highlights recommended changes to presentation elements, such as suggested color codes, font sizes, or layout adjustments. The user views these outputs and may select one of the improvement options or further adjust the design. The terminal packages the new configuration as updated design change information and transmits it back to the server.

In one embodiment, the server stores each iteration of design change information and feedback information in a log. By doing so, the server enables future retraining of the prediction model and the generative AI model using expanded datasets. The server also utilizes indices and caching mechanisms in the database and in the application layer to accelerate repeated retrieval of frequently accessed historical patterns. This reduces latency for real-time design optimization and improves the responsiveness of the system.

From a technical perspective, the server improves computer technology in several ways. By encoding design changes and historical behavior information into structured feature data and by using dedicated numerical computation devices for prediction, the server reduces the computational cost of evaluating multiple design alternatives compared to performing numerous conventional A/B tests or manual analyses. The server, by automatically constructing prompt sentences that embed numeric predictions and contextual cues, causes the generative AI model to generate focused and relevant qualitative insights, reducing the need for human operators to manually craft context each time. This coordination between numerical prediction and generative text production results in fewer required iterations and reduced network traffic, as the server can return both quantitative and qualitative information in a single response.

Furthermore, the server utilizes non-conventional processing rules. Rather than simply classifying or regressing on static feature vectors, the server specifically associates structured feature data with natural language prompts and integrates the predictions into language generation. The server enforces constraints on the prompt sentence format, such as including explicit indicator values, user segment identifiers, and design element descriptors. This discipline in the internal representation leads to more stable and reproducible outputs and allows the system to systematically compare design alternatives at scale.

The learning procedure of the prediction model and the generative AI model also contributes to technical improvements. By defining specific loss functions that balance prediction accuracy across multiple indicators and by using regularization methods, the server reduces overfitting and improves generalization to new design changes. The server may apply mini-batch training, gradient clipping, and early stopping criteria to optimize training time and resource usage. For the generative AI model, the server may perform fine-tuning using domain-specific conversation logs and explanation texts, thus tailoring the model to interface design scenarios and reducing incoherent responses. These methods collectively improve the precision and consistency of outputs, which in turn reduces the number of server-client exchanges required for a satisfactory optimization.

In another embodiment, the server reduces communication load by generating multiple improvement options in a single response. The server, based on the predicted indicator values and constraints specified by the user, requests the generative AI model to propose several alternative designs in one natural language response. The server then encodes these alternatives into compact identifiers and corresponding parameter sets, which the terminal can store locally. The user can switch between alternatives on the terminal without contacting the server for each trial, thereby reducing network traffic and improving responsiveness. In yet another embodiment, the server adopts a modular architecture, in which separate submodules handle feature extraction, prediction, prompt generation, language generation, and feedback assembly. Each submodule has defined input and output data structures, permitting substitution of different model types without changing the overall system behavior. For example, the server may replace the neural network-based prediction model with a tree-based model or may integrate a different generative AI model with a modified prompt format. This modular design improves maintainability and scalability and allows the server to adapt to hardware constraints, such as changing the numerical computation device or using different levels of precision for tensor operations.

In some embodiments, the system is applied not only to electronic commerce pages but also to other digital presentations, such as dashboard interfaces, educational content pages, or media streaming interfaces. In each case, the server treats presentation elements as feature vectors, historical behavior data as target indicators, and design changes as transformations in feature space. The generative AI model explains and interprets the predicted effects for domain-specific user groups. The server's ability to generalize across presentation types while maintaining the same technical flow demonstrates that the system is not limited to a particular business process but rather improves the underlying computer processing for interactive design evaluation.

Through these embodiments, the server, the terminal, and the user cooperate to realize a system in which complex predictive modeling and generative reasoning are tightly coupled in a technically specific manner. The server performs structured data processing, feature generation, model inference, prompt construction, and integrated feedback generation that go beyond mere automation of human decision-making. The system thereby improves processing speed, prediction accuracy, communication efficiency, and usability of the computing environment itself, and enables real-time optimization of digital designs that would not be feasible using conventional manual or purely numerical analysis methods.

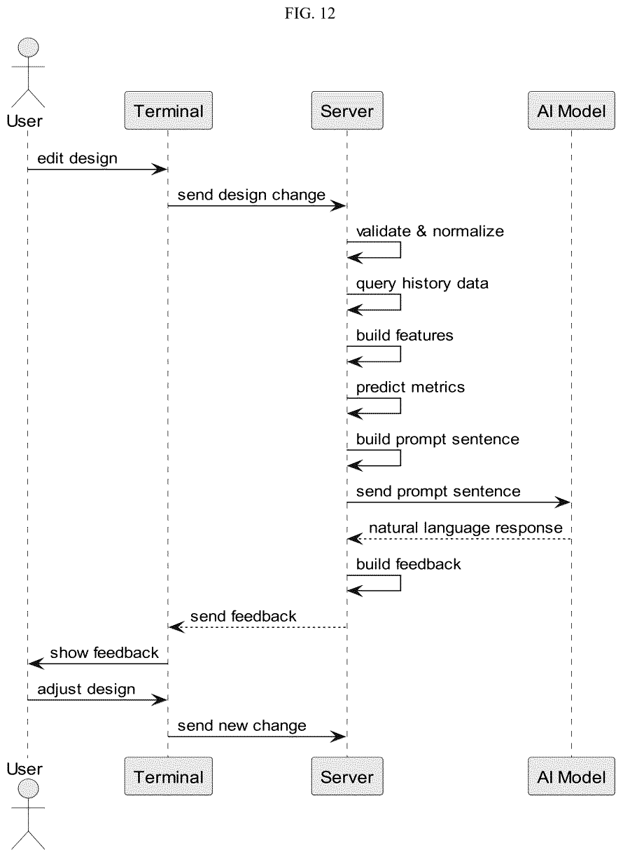

The following describes the processing flow using FIG. 12.

### Step 1

User operates the terminal to modify one or more presentation elements of a digital page, such as a background region, a text region, or a button.

User inputs new values (for example, a new color code, font size, or layout option) through a graphical editor displayed on the terminal.

Terminal receives, as input, the user's editing operations and converts them into structured design change information including at least a page identifier, element identifiers, and before-change and after-change property values.

Terminal outputs the design change information by transmitting it as a request to the server over a network using a communication protocol.

### Step 2

Server receives, as input, the design change information from the terminal through a network interface.

Server parses the request to extract a page identifier, a list of presentation elements, and associated property changes, and validates that each identifier and value falls within predetermined constraints.

Server performs data validation and normalization of formats (for example, converting color names into color codes and standardizing units for sizes), thereby generating normalized design change data as output for subsequent processing.

### Step 3

Server receives, as input, the normalized design change data and uses a database subsystem to query storage for past change history information matching criteria such as page type, element type, and value ranges.

Server also retrieves behavior history information linked to those past changes, including click events, conversion events, dwell times, and revenue values.

Server performs join and filter operations on these records based on keys such as page identifier, time window, and user segment, and outputs associated learning input information that pairs design changes with corresponding behavior outcomes.

### Step 4

Server receives, as input, the learning input information and applies preprocessing operations using a numerical data processing library.

Server encodes categorical attributes (for example, colors, fonts, layouts, device categories) into numerical representations using encoding schemes such as one-hot encoding or embedding indices.

Server normalizes numerical attributes (for example, click-through rate, conversion rate, dwell time, revenue) using scaling formulas to map them into a consistent numeric range.

Server concatenates encoded categorical values and normalized numerical values into feature vectors, and outputs feature data formatted as multi-dimensional arrays or tensors suitable for input to a prediction model.

### Step 5

Server receives, as input, the feature data and the current normalized design change data, and loads a trained prediction model into memory on a numerical computation device such as a central processing unit or graphics processing unit.

Server inputs the feature data to the prediction model and performs numerical operations including matrix multiplications, activation function evaluations, and normalization operations according to the model architecture.

Server computes predicted values of indicators such as click-through rate, conversion rate, and revenue-related metrics for the proposed design, and outputs these predicted indicator values as structured numerical data.

### Step 6

Server receives, as input, the normalized design change data, contextual information (for example, user segments and device types), and the predicted indicator values generated in Step 5.

Server constructs a prompt sentence by concatenating these inputs into a natural language sequence according to a predefined template.

For example, the server may produce as output a prompt sentence such as: “Predict the impact on click-through rate and conversion rate when the background color of the product page is changed from blue to green. Use historical data of similar color changes and explain the reasoning for different user segments on mobile devices and desktop devices.”

### Step 7

Server transmits, as input to a generative AI model, the constructed prompt sentence and, optionally, textual representations of the predicted indicator values.

Server executes the generative AI model on a numerical computation device, tokenizing the prompt sentence and computing attention and feed-forward operations through the model's layers.

Server obtains, as output, a natural language response that includes qualitative insights explaining why the predicted effects may occur and improvement proposals suggesting alternative design options or refinements.

### Step 8

Server receives, as input, the predicted indicator values from Step 5 and the natural language response from Step 7.

Server applies text analysis operations, such as keyword detection or pattern matching, to the natural language response to extract explicit recommendations and user sentiment indications.

Server combines the numerical predictions and extracted textual information into feedback information that includes quantitative evaluation information (for example, predicted percentage changes relative to baseline) and multiple improvement options represented as structured records.

Server outputs the feedback information in a data structure suitable for transmission to the terminal.

### Step 9

Server receives, as input, the assembled feedback information and formats it into a response message, including fields for indicator values, baseline comparisons, graphs data, summary text, and detailed suggestions.

Server may compress or otherwise optimize the response structure to reduce message size and to organize alternative design options under compact identifiers.

Server outputs the formatted response message by transmitting it to the terminal via the network.

### Step 10

Terminal receives, as input, the response message containing the feedback information from the server.

Terminal parses the message and maps numerical fields to visualization components and textual fields to display widgets in the user interface.

Terminal generates graphical output such as charts for indicator changes and textual output such as summaries and recommended design changes, and presents them to the user on a display device.

### Step 11

User reviews, as input, the feedback information displayed on the terminal, including predicted indicator values, qualitative explanations, and suggested improvement options.

User selects one of the recommended options or modifies the design further by adjusting presentation elements based on the feedback, for example, changing a color shade, repositioning a button, or altering font size.

Terminal converts these new or adjusted design choices into updated design change information and outputs a new request to the server, which is then processed again starting from Step 2.

### Step 12

Server receives, as input, repeated design change information and associated iterative evaluation requests from the terminal during a design session.

Server reuses cached feature extraction results where applicable, and selectively recomputes predictions and generative outputs only for changed elements to reduce processing time and resource usage.

Server outputs updated predicted indicator values and revised natural language responses, thereby enabling a real-time, iterative optimization loop in which each cycle refines the design based on both numerical and qualitative computer-generated information.

It is also possible to incorporate an emotion engine for estimating the user's emotions. That is, the specific processing unit 290 may estimate the user's emotions using an emotion identification model 59, and perform specific processing based on the estimated emotions.

### Example 2

Description follows regarding a flow of the specific processing in an Example 2. The units of the system described below are implemented by the data processing device 12 and the smart device 14. The data processing device 12 is called a “server” and the smart device 14 is called a “terminal”.

Conventional user interface optimization techniques in computing systems typically rely on static design guidelines, manual analysis of operation logs, and offline experimentation. In such techniques, operation histories are often collected in an ad-hoc manner and analyzed with fixed heuristics or manually crafted rules, which are not well suited to capturing complex, evolving user behavior patterns. As a result, it is difficult for a computing system to automatically and continuously adapt user interface configurations, such as arrangement, dimension, and color of screen elements, to actual usage tendencies of users. Furthermore, while generative AI models have emerged as powerful tools for pattern discovery and content generation, existing systems frequently treat these models as black-box assistants, issuing free-form queries and manually interpreting the outputs. In typical implementations, there is no systematic mechanism for generating structured prompt sentences that bind together: (i) preprocessed behavioral data, (ii) usability indices, and (iii) design structure information, in a way that allows the generative AI model to produce reproducible, machine-usable interface configuration proposals. Consequently, the interaction between the computing system and the generative AI model is brittle, non-repeatable, and heavily dependent on manual intervention.

In addition, conventional systems that attempt to evaluate design changes in user interfaces tend to focus on offline A/B testing or coarse-grained performance metrics. These systems do not integrate a feedback loop in which (a) user operation histories under different interface configurations are continuously collected and preprocessed, (b) generative AI models are guided by explicit prompt sentences to analyze usage tendencies and to predict the impact of new interface proposals, and (c) the resulting proposals are structured so that they can be automatically presented to and selectively adopted by user terminals. This lack of an integrated feedback architecture prevents efficient, real-time improvement of computer-based user interfaces.

Moreover, qualitative insights about user experience are usually obtained through human interviews and manual analysis, which are costly, time-consuming, and difficult to scale. Existing computer-implemented solutions do not effectively use generative AI models to perform simulated qualitative interviews in a structured manner, powered by actual behavioral data, nor do they convert such qualitative signals into actionable configuration proposals and understandable reports. As a result, there is a gap between raw behavioral logs, high-level UX insights, and concrete UI modifications that can be deployed in real systems.

Therefore, there is a need for an improved computer-implemented technique that (i) systematically generates prompt sentences for a generative AI model based on preprocessed operation histories, usability indices, and design structure information, (ii) obtains machine-usable analysis results and interface configuration proposals from the generative AI model, (iii) provides a closed feedback loop that incorporates user adoption information and post-change behavioral data, and (iv) produces both quantitative reports and qualitative insights in a form easily understood by users. Such a technique should improve the functioning of computer systems by enabling automated, data-driven, and iterative optimization of user interfaces, reducing reliance on manual analysis and heuristic rules.

The specific processing by the specific processing unit 290 of the data processing device 12 in Example 2 is realized by the following means.

The present invention provides a server comprising a processor configured to generate prompt sentences that instruct analysis of information structures related to designs and application of statistical estimation processes; generate prompt sentences that instruct collection of behavioral information related to user operation histories and evaluation of usability indices; generate prompt sentences that instruct analysis of difference information related to design modifications and prediction of influences of the design modifications on the usability indices and the behavioral information; acquire, from a storage apparatus, behavioral information related to the user operation histories and preprocess the behavioral information by using a data processing program, the preprocessing including at least completion of missing values and normalization; generate prompt sentences that instruct a generative AI model to analyze usage tendencies of users on the basis of the preprocessed behavioral information and the usability indices, and acquire analysis results related to the usage tendencies from the generative AI model; generate, on the basis of the acquired analysis results and the information structures related to the designs, configuration proposals of user interfaces including at least arrangement, dimension, color, and other display attributes of screen elements, and transmit the configuration proposals to user terminals; generate prompt sentences that instruct generation of interview scenarios and analysis of response content by the generative AI model to extract qualitative insights related to subjective evaluations and latent requirements of users; and generate prompt sentences that specify summary content, explanation content, and visualization formats for converting prediction results and analysis results returned by the generative AI model into quantitative report formats and user interface improvement proposal formats, and cause presentation information generated according to the summary content, the explanation content, and the visualization formats to be transmitted to the user terminals. This enables a computing system to automatically and iteratively improve user interface configurations by tightly integrating data collection, preprocessing, structured prompt generation, generative AI-based analysis, configuration proposal generation, user feedback acquisition, and report generation, thereby enhancing the technical performance of the system in adapting to user behavior and reducing reliance on manual, heuristic-based optimization.

The term “information structure related to a design” refers to data representing logical or visual organization of elements in a user interface or other designed artifact, including at least identifiers, hierarchy, layout relationships, and attribute definitions for individual elements.

The term “statistical estimation process” refers to a computational procedure that derives inferred values, predictions, or parameter estimates from input data using statistical methods, such as regression analysis, probability modeling, or distribution fitting.

The term “prompt sentence” refers to text or structured linguistic content supplied to a generative AI model, the text or content specifying an instruction, a task description, input context, or an output format to control processing by the generative AI model.

The term “behavioral information” refers to data representing actions taken by a user when operating a computing system, including at least event types, timestamps, element identifiers, navigation paths, and contextual attributes associated with the actions.

The term “user operation history” refers to a chronological record of behavioral information accumulated over time that reflects how a user or a group of users interacts with a user interface or other system functions.

The term “usability index” refers to one or more quantitative measures that represent ease of use or effectiveness of a user interface, including metrics such as task completion rate, error rate, time to complete a task, and number of interactions.

The term “design modification” refers to a change made to a design, including but not limited to altering arrangement, dimension, color, content, or interaction behavior of one or more elements in a user interface.

The term “difference information” refers to data describing a comparison between a first design state and a second design state, including at least which elements are modified, what attributes are changed, and the magnitude or qualitative nature of the changes.

The term “storage apparatus” refers to any hardware or virtual component capable of persistently or semi-persistently storing data, including but not limited to magnetic storage, solid-state storage, optical storage, or network-based storage.

The term “data processing program” refers to executable instructions that cause a processor to perform operations on data, including loading, transforming, aggregating, filtering, and formatting data for subsequent analysis.

The term “completion of missing values” refers to a process of detecting absent or undefined entries in a dataset and assigning substitute values based on predetermined rules, statistical inference, or heuristics to make the dataset more suitable for analysis.

The term “normalization” refers to transforming data values into a standardized numeric range or scale, or into a normalized representation, so as to reduce scale differences among features and improve stability or comparability of analysis.

The term “generative AI model” refers to a computational model based on machine learning or artificial intelligence that is capable of generating new data or content, such as text, code, or structured information, in response to an input prompt sentence.

The term “usage tendency” refers to a pattern or trend in user behavior derived from behavioral information, including preferences for particular functions, common navigation paths, typical times of use, and recurrent interaction sequences.

The term “analysis result related to the usage tendency” refers to an output generated by a generative AI model or another analysis mechanism that describes or quantifies usage tendencies, including identified patterns, clusters, segments, or predicted behaviors.

The term “configuration proposal of a user interface” refers to a machine-usable specification of a suggested arrangement or modification of user interface elements, including at least positional, dimensional, visual, and interaction-related attributes.

The term “screen element” refers to a discrete visual or interactive component displayed on a user interface, including buttons, text fields, icons, images, menus, panels, and other graphical or interactive objects.

The term “user terminal” refers to an endpoint device through which a user interacts with a system, including but not limited to a smartphone, tablet, personal computer, or other computing device having a display and input capabilities.

The term “adoption information” refers to data indicating whether, how, or to what extent a user or a user terminal accepts, rejects, or partially applies a configuration proposal of a user interface.

The term “simulated qualitative interview” refers to an artificial conversation generated by an AI system that imitates a human-conducted interview aimed at eliciting subjective opinions, perceptions, or latent requirements from the perspective of a user.

The term “interview scenario” refers to structured content defining a flow of a simulated qualitative interview, including at least dialogue steps, question items, follow-up conditions, and objectives of the interview.

The term “response content” refers to textual or structured outputs produced by a generative AI model during a simulated qualitative interview, where the outputs simulate answers given by hypothetical or representative users.

The term “qualitative insight” refers to non-numerical understanding derived from response content or behavioral information, including perceived problems, motivations, expectations, and latent requirements of users.

The term “subjective evaluation” refers to an assessment expressed or inferred in terms of user feelings, satisfaction, preference, or perceived quality, rather than purely objective performance metrics.

The term “latent requirement” refers to a user need or expectation that is not explicitly expressed in operation logs or direct feedback, but is inferred from behavioral information or qualitative analysis.

The term “summary content” refers to information that defines how prediction results or analysis results are condensed into a shorter or higher-level representation suitable for presentation or reporting.

The term “explanation content” refers to information that clarifies reasoning behind a prediction result, an analysis result, or a configuration proposal, including causal hypotheses, contributing factors, and plain-language descriptions.

The term “visualization format” refers to a specification of how data, prediction results, or analysis results are graphically presented, including charts, graphs, tables, diagrams, and layout structures.

The term “quantitative report format” refers to a structured representation of numerical or statistical data, such as metrics, trends, and comparisons, suitable for inclusion in dashboards, reports, or analytical documents.

The term “user interface improvement proposal format” refers to a structured representation of recommended changes to a user interface, including element identifiers, proposed attribute values, rationales, and expected effects.

The term “presentation information” refers to data assembled for display to a user, including text, visualizations, and structured explanations, generated according to specified summary content, explanation content, and visualization formats.

In one embodiment, a server, a terminal, and a user cooperate to implement the invention. The server comprises at least one processor, a main memory, a non-volatile storage apparatus, and a network interface. The terminal comprises a display device, one or more input devices, a local processor, and a communication interface. The user operates the terminal to interact with a graphical user interface provided by an application program. The server executes server-side application programs, data processing programs, and a generative AI model execution program under an operating system, and communicates with the terminal through a network such as the Internet.

The server stores, in the storage apparatus, a log database, a design metadata database, a prompt template repository, a model configuration repository, and a generated UI configuration repository. The server implements the log database on a relational database system such as a general-purpose SQL database, and stores structured tables including, for example, a user table, a session table, and an operation log table. The server defines the operation log table with fields such as user identifier, session identifier, timestamp, page identifier, element identifier, event type, device type, layout version identifier, and additional context fields. The server defines the design metadata database as data describing an information structure related to a design. The server represents, as design metadata, a hierarchical tree or directed graph of interface components, where each node represents a screen element and contains attributes such as element identifier, type, logical role, default layout parameters (position, width, height, z-index), and style attributes (color, font, border). The server manages this metadata in a structured format such as a relational schema or a hierarchical document structure.

The server executes a data processing program implemented, for example, using a high-level programming language environment and a data analysis library such as a data frame library. The server uses this library to load operation logs from the log database into an in-memory data frame. The server carries out missing value completion by detecting null or invalid fields for timestamps, page identifiers, or device types and replacing them according to predetermined rules. The server sets, for example, a missing device type to a default category such as “unknown_device,” and infers a missing page identifier by joining with session and URL information stored in auxiliary tables. The server performs normalization of numerical fields such as click count per element, dwell time per page, and session length by applying, for example, min-max normalization or z-score normalization. The server maintains a feature matrix in which each row corresponds to a user-page or user-element pair, and each column corresponds to a numerical or categorical feature derived from the operation logs and the design metadata.

The server configures a generative AI model as a neural network model. In one embodiment, the server uses a transformer-based neural network architecture having multiple encoder-decoder layers, multi-head self-attention modules, and feed-forward sublayers. The server maintains model parameters including weight matrices and bias vectors for attention, feed-forward, and embedding layers. The server trains the generative AI model in advance on a corpus of interaction logs, design descriptions, and usability annotations. The server uses a supervised learning scheme in which input sequences consist of textual descriptions of usage statistics and design structures, and output sequences consist of recommended UI configuration descriptions and explanatory text. The server uses a loss function such as cross-entropy over token sequences, and updates the model parameters using a gradient-based optimization algorithm such as stochastic gradient descent with adaptive learning rate. The server optionally performs data augmentation by generating synthetic design variants and associated interaction statistics, thereby improving robustness of the model to diverse interface structures.

The server defines internal feature representations for the generative AI model. The server encodes, as input tokens, numerical metrics (for example, click frequencies and time-on-page) by discretizing them into intervals or by attaching them to tokens through learned embeddings. The server encodes element identifiers, page identifiers, and device types as categorical embeddings. The server concatenates, in the input sequence, textual tokens representing the task instruction (contained in a prompt sentence), followed by structured tokens representing aggregated behavioral features and design structure features. The server thus causes the generative AI model to process, in a unified manner, task instructions, usage statistics, and design metadata.

The server generates a prompt sentence based on prompt templates stored in the prompt template repository and on current behavioral data and design metadata. The server selects, for example, a template for usage pattern analysis and UI optimization. The server fills template slots with concrete metrics, such as names or identifiers of highly clicked elements, average dwell times, or error rates. The server adds to the prompt sentence a description of the data schema, so that the generative AI model can consistently interpret column names and values. An example prompt sentence generated by the server for usage tendency analysis and UI configuration proposal is:

“You are an expert in user interface optimization. The following data summarizes user click counts, unique user counts, and average time on page for each page and UI element, grouped by device type and time of day. Analyze the main usage tendencies, identify which elements are critical for task completion, and propose concrete changes to the user interface, including new positions, sizes, and colors for the most important elements. Respond in a structured textual form indicating, for each page and element, the current issue, the proposed change, and the expected effect on usability metrics.”

The server transmits this prompt sentence, together with a textual or tokenized representation of aggregated feature tables, to the generative AI model execution program. When the generative AI model executes on a remote inference service, the server sends the prompt sentence as part of an API request using a network protocol such as HTTPS. When the generative AI model executes on local hardware, the server passes an in-memory representation of tokens to the model inference engine. The server sets decoding parameters such as maximum output length, temperature, and sampling strategy to ensure that the output is deterministic enough for machine processing while still leveraging learned generalization. The server receives, from the generative AI model, one or more sequences of tokens constituting an analysis result related to usage tendencies and one or more configuration proposals of a user interface. The server interprets the sequences using a deterministic parser that identifies, for each line or segment of the output, fields such as page identifier, element identifier, current usability issue (for example, “too many taps required,” “element is below the fold,” “low visibility on mobile”), and proposed UI change (for example, “move to top of screen,” “increase width by 30%,” “change color to high-contrast accent”). The server validates that the element identifiers and page identifiers in the configuration proposals exist in the design metadata database. When a proposal refers to unknown identifiers, the server discards or corrects such entries using fallback rules.

The server converts configuration proposals into concrete layout parameters. The server maps abstract recommendations such as “move to top-right corner” into coordinate or constraint changes appropriate for the target UI framework. For example, when the terminal uses a constraint-based layout system, the server translates “move to center” into a pair of alignment constraints anchored to the parent container. When the terminal uses a flexbox layout system, the server translates “increase size” into updates to flex grow or basis properties. The server stores, in the generated UI configuration repository, one or more candidate configurations per user segment, per device type, or per individual user, along with metadata describing the expected effect on usability indices and a version identifier.

The server also generates a prompt sentence for a simulated qualitative interview. The server selects a template that defines the role of the generative AI model as a virtual user or as a UX researcher. The server fills the template with aggregated behavioral information and usability indices, for example:

“Based on the following aggregated usage data (high click frequency on the ‘Save’ control, long time on settings pages, frequent back-and-forth navigation), simulate a qualitative interview with a typical user of the application. Generate both the interviewer questions and the user answers. Focus on frustrations, expectations, and reasons why the user frequently uses the ‘Save’ control. Summarize at the end the key qualitative insights and latent requirements that could guide interface improvements. ”

The server transmits this prompt sentence and associated data to the generative AI model and obtains response content that simulates an interview. The server applies a text analysis algorithm to the response content, such as keyword extraction, sentiment scoring, and clustering of themes, to derive qualitative insights. The server stores these insights as structured records linked to specific elements, pages, or workflows.

The server further generates a prompt sentence for summary, explanation, and visualization. The server constructs an instruction that specifies how prediction results and analysis results should be reformatted:

“Summarize the predicted effects of the proposed user interface changes on task completion time, error rate, and number of required interactions. Explain, in plain language, why each change is expected to have the described effect, and suggest appropriate visualization types (for example, bar chart, line graph, or table) for presenting the metrics to stakeholders.”

The server receives, from the generative AI model, structured text recommending summary structures and visualization formats. The server then uses a report generator component to instantiate concrete charts and tables using a data visualization library. The server outputs these visualizations to the terminal for display.

The terminal receives, from the server, configuration proposals and presentation information. The terminal parses the configuration proposals and prepares one or more alternative layouts in its UI framework. When the terminal executes a native application, the terminal represents layout information as auto layout constraints, constraint sets, or component properties. When the terminal executes a browser-based application, the terminal represents layout information as style rules or layout configuration objects. The terminal maintains both an original configuration and a proposed configuration for each relevant screen. The terminal renders, on the display, a preview mode in which the user can toggle between the current configuration and the proposed configuration. The terminal highlights modified elements, for example, by overlaying outlines or labels, so that the user can easily recognize changes.

The user views the preview of the proposed user interface on the terminal and decides whether to adopt the proposed configuration. The user may adopt all proposed changes at once, or may adopt changes individually for each element. The user's selections constitute adoption information. The terminal records the adoption information in association with the user identifier and layout version identifiers, and transmits the adoption information to the server. The terminal then applies the adopted configuration to the active user interface by updating local configuration storage and re-rendering the relevant screen.

The server receives adoption information and stores it in the log database and the generated UI configuration repository. The server associates subsequent operation logs with the adopted configuration by attaching layout version identifiers. The server thus captures a post-change operation history under each configuration. The server subsequently performs the same preprocessing and analysis pipeline on the post-change data, allowing the generative AI model to compare before-and-after behavior and refine future proposals. Because the server maintains a linkage between configuration versions, behavioral metrics, and generative AI outputs, the server can iteratively converge on improved configurations with reduced manual intervention.

This architecture improves computer technology in several ways. The server reduces processing time and computational load by performing structured preprocessing and feature extraction using a data frame library and statistical normalization. This reduces input dimensionality and variance before passing data to the generative AI model, which in turn improves inference speed and stability. The server reduces communication overhead by transmitting aggregated and normalized feature summaries rather than raw log streams, thereby lowering network bandwidth usage and latency. The server improves prediction accuracy because the generative AI model operates on consistent, well-defined features and structured prompt sentences, rather than on ad-hoc, free-form queries. The use of explicit prompt templates and deterministic parsing rules yields outputs that can be machine-applied without complex manual interpretation, reducing error rates in automatic UI reconfiguration. Furthermore, the server implements a non-conventional interaction between log analysis and neural network inference. Instead of merely automating human evaluation of logs, the server defines specific feature matrices, prompt schemas, and mapping rules from natural language outputs to layout parameters. These rules constrain and guide the operation of the generative AI model in a way that enables direct control of machine-executable configuration data. The server executes a closed-loop adaptation process in which UI changes are not only suggested but also encoded, deployed, and evaluated under tracked configuration versions. This closed-loop design yields measurable technical effects such as reduction in average interaction steps and lower CPU and memory overhead on the terminal, because frequently used elements can be placed in positions requiring fewer redraws and fewer navigation transitions.

Alternative embodiments are also possible. In one variation, the server executes the generative AI model locally on a specialized processor, such as a graphics processing unit or dedicated neural network accelerator, thereby further reducing latency. In another variation, the server splits the generative AI model into a base model and a domain-adapted fine-tuned head, storing separate sets of weights and switching between them depending on application type or user segment. In yet another variation, the terminal performs a portion of the preprocessing locally, such as aggregating per-session metrics before transmission, to reduce the data volume sent to the server. In all such embodiments, the server, the terminal, and the user cooperate under the same conceptual framework: structured behavioral data and design metadata are transformed into prompt sentences, the generative AI model produces structured analysis results and configuration proposals, and the system applies and evaluates these proposals through concrete modifications of user interface configurations on actual hardware, thereby improving the technical performance and adaptability of the computing system.

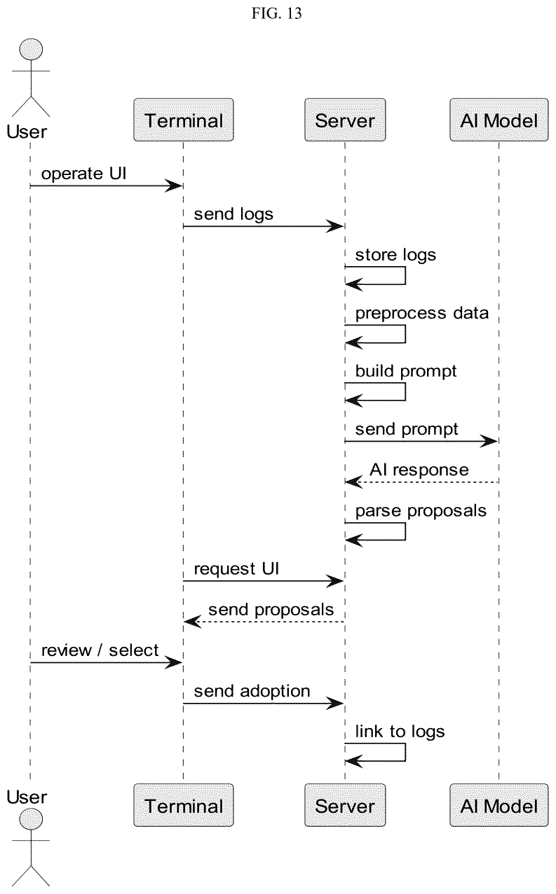

The following describes the processing flow using FIG. 13.

### Step 1

The terminal detects user operations and transmits operation events to the server.

The terminal receives, as input, low-level UI events such as button taps, page transitions, text input, and scroll actions generated by the user. The terminal converts each UI event into a structured record including fields such as user identifier, session identifier, timestamp, page identifier, element identifier, event type, device type, and current layout version identifier. The terminal aggregates a plurality of such records in a local buffer and, when a threshold count or a time interval is reached, the terminal sends the buffered records to the server via a network interface using a secure communication protocol such as HTTPS. As output, the terminal produces one or more request messages containing batched operation events, and the server receives these messages as input for subsequent processing.

### Step 2

The server validates and stores received operation logs in a log database.

The server receives, as input, one or more request messages containing batched operation events in a structured format such as JSON. The server parses each message, verifies the presence and validity of required fields (user identifier, timestamp, page identifier, element identifier, event type, layout version identifier), and rejects or corrects records with invalid or missing mandatory data. The server then inserts valid events into an operation log table of a relational database, storing each event as a row and indexing key columns such as user identifier and timestamp. As output, the server produces normalized operation log entries stored persistently in the database, and an acknowledgment message that is sent back to the terminal indicating successful storage.

### Step 3

The server retrieves raw operation logs and design metadata for preprocessing.

The server receives, as input, a preprocessing request triggered by a scheduler or an administrative command indicating a target time window and target user segment. The server queries the log database to extract all operation log entries within the specified time window and, in parallel, queries a design metadata database to retrieve information structures related to current designs, including page hierarchies and element attributes. The server loads the query results into an in-memory data structure such as a data frame for the logs and a graph or tree structure for the design metadata. As output, the server produces combined raw datasets that link behavior records to design elements by common identifiers.

### Step 4

The server performs data cleaning and feature extraction on the operation logs.

The server receives, as input, the combined raw datasets containing operation logs and design metadata. The server detects missing or inconsistent values in the operation logs, such as absent device types or incomplete page identifiers, and performs missing value completion by applying deterministic rules (for example, setting default categories) or by inferring values from correlated fields such as URL paths or previous events in the same session. The server then aggregates events by grouping on keys such as user identifier, page identifier, element identifier, device type, and time of day. The server computes, for each group, derived metrics including click count, unique user count, average dwell time, and task completion rate. The server normalizes continuous metrics using scaling methods such as min-max scaling or z-score normalization, thereby generating a feature matrix where each row represents a group and each column represents a normalized metric. As output, the server produces a cleaned and feature-enriched dataset that is suitable for input to a generative AI model.

### Step 5

The server summarizes behavioral features and design context into prompt-ready text.

The server receives, as input, the cleaned and feature-enriched dataset and the design metadata. The server selects a subset of records according to importance criteria, such as highest click frequency or lowest usability scores, in order to control prompt size. The server then converts each selected record into a concise textual description, for example, “On mobile devices, the ‘Save’ element on the settings page is clicked 5 times more often than other elements, with an average dwell time of 30 seconds.” The server also generates a brief description of the design structure, such as listing the hierarchy of elements on a page and their current layout attributes. The server concatenates these descriptions into a structured context string that can be embedded into a prompt sentence. As output, the server produces a textual context summary that encodes the feature matrix and design graph in human-readable form.

### Step 6

The server constructs a prompt sentence for usage tendency analysis and UI optimization.

The server receives, as input, the textual context summary and one or more prompt templates stored in a prompt template repository. The server selects a template suitable for analyzing usage tendencies and proposing user interface configuration changes. The server fills placeholders in the template with the context summary and with explicit instructions about expected output structure. For example, the server constructs a prompt sentence such as: “You are an expert in user interface optimization. The following data summarize user behavior per page and element: [context]. Analyze the main usage tendencies, identify critical elements, and propose specific changes to arrangement, size, and color for each critical element. Provide the result in sections: page_id, element_id, current_issue, proposed_change, expected_effect.” The server ensures that the final prompt sentence conforms to length limitations and contains clear task instructions. As output, the server produces a finalized prompt sentence ready for submission to the generative AI model.

### Step 7

The server invokes the generative AI model to obtain analysis results and configuration proposals.

The server receives, as input, the finalized prompt sentence and model configuration parameters such as model identifier, maximum token length, and decoding strategy. The server transmits the prompt sentence to a generative AI model engine, either via a local inference API or via a remote inference service using an HTTPS request. The server configures the generative AI model, which is implemented as a transformer-based neural network, with the specified parameters, and requests generation of an output sequence. The generative AI model processes the prompt sentence, internally applying learned attention weights and feed-forward computations over embedded tokens to infer patterns and generate recommended UI changes. The server receives the generated text output from the model, which includes both usage tendency analysis and proposed configuration changes. As output, the server produces a raw model response string that contains candidate configuration proposals in a semi-structured textual format.

### Step 8

The server parses the generative AI model output into structured configuration proposals.

The server receives, as input, the raw model response string. The server applies a deterministic parsing algorithm, such as regular expression matching or rule-based line parsing, to identify sections corresponding to page identifiers, element identifiers, current usability issues, proposed changes, and expected effects. The server validates parsed identifiers against the design metadata and discards entries containing unknown or invalid identifiers. The server then converts textual proposals into structured records that encode actions such as “move element to top,” “increase width by 30%,” or “change color to a high-contrast scheme,” mapping these to layout parameters understood by the terminal's UI framework. As output, the server produces a collection of normalized configuration proposal records, each record tied to specific design elements and annotated with estimated usability impacts.

### Step 9

The server stores configuration proposals and associates them with user segments and layout versions.

The server receives, as input, the collection of normalized configuration proposal records and information about target user segments or device types. The server writes each proposal into a generated UI configuration repository, recording fields such as proposed layout parameters, applicable page and element identifiers, target segment criteria, creation timestamp, and a new layout version identifier. The server may also compute and store priority scores for each proposal based on expected effect or frequency of affected elements. As output, the server produces persistent configuration proposal entries that can be retrieved by terminals and applied as alternative layouts for specific users or segments.

### Step 10

The terminal requests and receives configuration proposals from the server.

The terminal receives, as input, a display context including current user identifier, current page identifier, and device type when preparing to render a user interface screen. The terminal sends a request to the server, including these identifiers, to query for applicable configuration proposals. The server returns a set of proposals that match the user and device criteria as a structured payload. The terminal parses the payload and extracts layout parameters, such as new positions, sizes, and color schemes for specific elements on the current page. As output, the terminal produces an internal representation of one or more candidate layouts, including both the existing layout and any server-supplied alternative layouts.

### Step 11

The terminal renders a preview of the proposed user interface and collects adoption information from the user.

The terminal receives, as input, the internal representation of candidate layouts and presentation information such as textual explanations or expected effects. The terminal generates, in memory, a preview mode in which the current layout and a proposed layout are both constructed using the terminal's UI framework. The terminal displays the preview on the display device, allowing the user to switch between the current and proposed views and to inspect highlighted changes. The terminal renders controls, such as buttons or toggles, that permit the user to accept or reject each proposed change or the entire proposed layout. Based on the user's interactions, the terminal constructs adoption information records indicating which proposals were adopted or rejected. As output, the terminal sends the adoption information back to the server, and updates its own active layout configuration to reflect the adopted changes.

### Step 12

The server records adoption information and links it to subsequent operation histories.

The server receives, as input, the adoption information transmitted by the terminal, including user identifier, layout version identifiers, and adoption decisions for each proposal. The server stores this information in the log database and associates it with the corresponding configuration proposal entries in the generated UI configuration repository. The server updates mapping tables so that future operation logs for the user under the adopted configuration are tagged with the correct layout version identifier. As output, the server maintains a consistent linkage among proposals, adoption decisions, and subsequent behavioral data, enabling precise evaluation of proposal effectiveness.

### Step 13

The server reprocesses post-change behavior and refines future prompt sentences and proposals.

The server receives, as input, updated operation logs tagged with layout version identifiers after the user has adopted or rejected certain proposals. The server repeats the preprocessing, feature extraction, and summarization steps on these logs, now comparing pre-change and post-change metrics for each layout version. The server constructs new prompt sentences that explicitly include before-and-after statistics, such as “After moving the ‘Save’ element to the top of the screen, task completion time decreased by 20% and error rate decreased by 10%.” The server sends these enhanced prompt sentences to the generative AI model to obtain refined analysis results and more targeted configuration proposals. As output, the server produces updated proposals that better reflect observed effects, thereby continuously improving interface configurations based on concrete, versioned behavioral evidence.

### Application Example 2

Description follows regarding a flow of the specific processing in an Application Example 2. The units of the system described below are implemented by the data processing device 12 and the smart device 14. The data processing device 12 is called a “server” and the smart device 14 is called a “terminal”.

Conventional user interface optimization and digital experience design techniques suffer from several technical limitations in how computing systems collect, interpret, and act upon user data.

First, existing systems generally treat user operation logs and user emotion signals as separate, loosely coupled data streams. Usage logs may be used for coarse analytics, while emotion data, when used at all, is processed in isolated modules. As a result, the execution of UI adaptation logic on a processor is based on incomplete context, and the system cannot generate machine-interpretable layout instructions that jointly reflect both user behavior tendencies and emotion states. This leads to sub-optimal control of screen rendering, redundant server-client communication, and inefficient use of computing resources.

Second, in many systems, a generative AI model is called in an ad hoc manner, driven by manually crafted prompts. The prompts are not systematically derived from structured behavioral features, prediction outputs, and emotion recognition results. Because the processor does not have a standardized mechanism for generating prompt sentences from internal state and model outputs, the generative AI model often receives unstructured or inconsistent instructions. This degrades the quality, reproducibility, and latency of AI-generated UI configurations or information presentation strategies, and increases the computational overhead of post-processing verbose, unstructured output on the server.

Third, existing design support tools typically treat numerical prediction, qualitative feedback, and reporting as separate stages. Prediction engines may output raw numerical estimates, while qualitative feedback (e.g., from interviews) is obtained manually, and reports are composed by human operators. The processor therefore performs fragmented pipelines, repeatedly converting between formats and invoking separate applications. This fragmentation results in increased memory usage, I/O overhead, and latency, and hinders real-time or near real-time adaptation of interfaces on client devices.

Fourth, simulated qualitative evaluations using artificial intelligence are not tightly integrated with the core runtime. When AI is used to mimic user feedback, current systems generally run stand-alone simulations without feeding the results back into a unified prompt generation pipeline. Thus, the processor cannot systematically reuse insights from simulated qualitative evaluations together with quantitative predictions to drive adaptive UI control, campaign evaluation, or recommendation logic. This prevents the system from fully exploiting available model outputs and leads to inefficient or inconsistent decision making.

In addition, known systems usually do not convert the generative AI model's textual proposals into structured layout specifications in a standardized, machine-readable form that can be directly consumed by a rendering engine. Instead, human intervention or custom, brittle parsers are required, which increases processing complexity on the server and client, and limits the ability to deliver rapid, automated reconfiguration of user interfaces in response to changing behavior and emotion states.

Accordingly, there is a need for improved computer-implemented techniques in which a processor (i) acquires and aggregates usage data and emotion-related data, (ii) derives behavior indices and emotion states using prediction models, (iii) automatically generates structured prompt sentences for a generative AI model based on such context, (iv) converts AI-generated proposals into structured layout information, and (v) uses that layout information to directly control rendering on a display device. There is also a need for the processor to generate prompt sentences that orchestrate simulated qualitative evaluations and integrate quantitative evaluation results with extracted insights into machine-generated reports. By addressing these needs, the invention improves the operation of the computer system itself by reducing manual configuration, improving consistency and efficiency of AI invocation, and enabling more responsive and resource-efficient UI adaptation and reporting pipelines.

The specific processing by the specific processing unit 290 of the data processing device 12 in Application Example 2 is realized by the following means.

The present invention provides a server comprising a processor and a storage resource, the processor being configured to acquire usage data from one or more client devices and store the usage data in the storage resource, to extract feature values representing usage tendencies from the stored usage data and predict user behavior indices based on the feature values by using one or more prediction models, to acquire emotion-related data including at least one of image data and audio data and identify user emotion states from the emotion-related data by using an emotion recognition model, to generate prompt sentences for a generative AI model based on context information including the user behavior indices and the user emotion states so as to cause the generative AI model to generate screen configuration modification proposals or information presentation methods, to input the prompt sentences into the generative AI model and obtain, from the generative AI model, output proposals, to convert the output proposals into structured layout information specifying arrangement or presentation of interface elements, and to control display screens presented on the client devices in accordance with the structured layout information, the processor being further configured to generate prompt sentences for instructing analysis of design elements and application of prediction computation processing, to generate prompt sentences for instructing collection and evaluation of operation histories to perform usability evaluation processing, to generate prompt sentences for instructing analysis of design change content and evaluation of influence caused by the design change content, to generate prompt sentences for instructing execution of simulated qualitative evaluation processing including generation of evaluation scenarios and extraction of insights from response information groups, and to generate prompt sentences for instructing integration of quantitative evaluation results and the insights into report information understandable to a user. This enables the computer system to automatically and consistently orchestrate prediction models and a generative AI model via machine-generated prompt sentences, to transform heterogeneous behavioral, emotional, and qualitative signals into structured layout instructions, to directly drive dynamic user interface rendering and information presentation on client devices with reduced manual intervention and reduced parsing overhead, and to generate integrated, machine-constructed reports, thereby improving the technical performance, responsiveness, and resource efficiency of the underlying computing infrastructure.

The term “usage data” refers to information indicating operations performed by a user on an information processing device, including at least events such as selections, activations, scrolling operations, screen transitions, text inputs, and time stamps associated with such events.

The term “storage resource” refers to a hardware or software component capable of storing data, such as a memory device, a magnetic or optical storage device, or a database system, that retains usage data, model parameters, and structured layout information.

The term “feature values” refers to numerical or categorical values derived from raw data, including aggregated counts, ratios, time durations, or encoded attributes, which represent characteristics of user behavior or other conditions and are used as inputs to an information processing model.

The term “usage tendencies” refers to patterns or preferences in user behavior inferred from usage data, including frequencies of use of particular functions, typical navigation paths, and common termination points of sessions.

The term “user behavior index” refers to a quantitative indicator predicted by a model based on feature values, such as a probability of selection, a predicted session length, a predicted conversion rate, or another numerical measure of user behavior.

The term “information processing model” refers to a computational model implemented in software and executed by a processor, including at least statistical models and machine learning models, that receives feature values as input and outputs predicted values or classifications.

The term “emotion-related data” refers to sensor data or derived data relating to a user's emotional state, including at least image data representing a facial expression, audio data representing a voice, or text data derived from such audio, and any features extracted therefrom.

The term “user emotion state” refers to a categorized or parameterized representation of a user's emotion, such as stress, confusion, joy, curiosity, or neutrality, identified from emotion-related data by an emotion recognition process.

The term “emotion recognition model” refers to a computational model, such as a neural network or another pattern recognition algorithm, that receives emotion-related data as input and outputs one or more user emotion states or associated confidence values.

The term “context information” refers to combined information including at least a user behavior index and a user emotion state, and optionally further including device characteristics, task type, or environmental conditions, which is used to generate instructions for a generative AI model.

The term “generative AI model” refers to an artificial intelligence model that generates new data, such as natural language text or structured representations, in response to input, and that has been trained using machine learning techniques to perform generation tasks conditioned on prompt sentences.

The term “prompt sentence” refers to a sequence of one or more characters representing an instruction, query, or context description, which is provided as input to a generative AI model to control the behavior of the generative AI model and to specify a generation task.

The term “screen configuration modification proposal” refers to information indicating a proposed change to an arrangement, appearance, or composition of user interface elements on a display screen, including suggested positions, sizes, visibility, or emphasis of such elements.

The term “information presentation method” refers to a way of presenting information to a user, including but not limited to ordering of content, grouping of items, choice of wording, level of detail, and selection of interaction flow.

The term “output proposals” refers to one or more data structures or text segments generated by a generative AI model in response to a prompt sentence, including at least a screen configuration modification proposal or an information presentation method.

The term “structured layout information” refers to machine-readable data defining a configuration of user interface elements, including identifiers of elements, positional parameters, hierarchical relationships, and presentation attributes, in a format interpretable by a rendering engine.

The term “display screen” refers to an output region provided by a display device of a client device, such as a monitor, a touch screen, or a head-mounted display, on which user interface elements are rendered according to structured layout information.

The term “client device” refers to a computing device operated by a user, including at least a terminal, a mobile communication device, a wearable device, or another user-operated device, which communicates with a server and presents a display screen.

The term “design elements” refers to constituent parts of a user interface or content design, including at least colors, fonts, shapes, icons, images, layout structures, interactive controls, and arrangement rules.

The term “prediction computation processing” refers to processing in which an information processing model receives input data representing design elements or usage features and outputs predicted numerical values or labels representing expected outcomes or effects.

The term “operation history” refers to a chronological series of usage data items relating to operations performed by a user or users on an interface or system over one or more sessions.

The term “usability evaluation processing” refers to processing that assesses the ease, efficiency, or satisfaction associated with use of an interface or system, based on operation history and optionally prediction results.

The term “design change content” refers to information describing a modification of one or more design elements, including addition, deletion, or alteration of user interface components, layout, or visual attributes.

The term “influence caused by the design change content” refers to a predicted or evaluated effect that the design change content has on user behavior indices, usability, performance metrics, or other system-related outcomes.

The term “simulated qualitative evaluation processing” refers to processing in which artificial intelligence generates text-based responses as if from users, based on predefined scenarios and questions, to emulate qualitative feedback without real human participants.

The term “evaluation scenario” refers to a description used in simulated qualitative evaluation processing, including at least one virtual user attribute, such as demographic or proficiency information, and one or more question contents regarding an interface, product, or concept.

The term “virtual user attribute” refers to an attribute of a hypothetical user profile, such as age range, region, knowledge level, interest, or usage context, that characterizes a virtual participant in a simulated qualitative evaluation.

The term “question content” refers to an inquiry or prompt presented to a real or virtual user in an evaluation scenario, requesting opinions, impressions, or experiences regarding a design, interface, or proposal.

The term “response information group” refers to a plurality of response data items generated by a generative AI model or obtained from participants, each response corresponding to at least one evaluation scenario and question content.

The term “insights” refers to extracted findings or interpretations derived from analysis of a response information group, identifying common issues, preferences, patterns, or opportunities for improvement.

The term “quantitative evaluation result” refers to a numerical output produced by a prediction computation processing or a generative AI model, such as estimated performance metrics, probabilities, or aggregated scores.

The term “report information” refers to data representing a structured explanation or summary of evaluation results, including textual descriptions, numerical indicators, and optionally structured sections, that is formatted for human understanding.

In one or more exemplary embodiments, a server cooperates with one or more terminals to implement the claimed system. The server includes at least one processor, a memory, a non-volatile storage device, and a communication interface. The terminal includes at least one processor, a memory, a display device, one or more input devices such as a touch panel, and optionally one or more sensors such as a camera and a microphone. The server and the terminal communicate over a communication network using a specified protocol.

The server stores, in the storage device, executable programs and model parameters implementing an information processing model, an emotion recognition model, and a generative AI model interface. The information processing model and the emotion recognition model are implemented, for example, using machine learning libraries such as a numerical computation framework and a deep learning framework. The generative AI model is accessed, for example, via an external model serving interface or an internal sequence-to-sequence generation module.

The terminal executes an application that renders a user interface on the display device. The terminal records usage data by generating event records whenever the user interacts with the user interface. Each event record includes a user identifier, a session identifier, an event type (for example, a button selection, a scrolling operation, a screen transition, or a text input), a timestamp, an element identifier, and additional parameters such as a scroll distance or an input length. The terminal buffers such event records in an in-memory queue and periodically transmits the buffered records to the server via the communication interface using a structured data format.

The server stores the received usage data in the storage resource as rows in one or more tables. In one embodiment, the server uses a relational database management system to store the usage data in a normalized schema including a user event table, a session table, and a feature table. The user event table stores raw events, and the feature table stores feature values derived from aggregated events. The server executes data processing programs implemented in a general-purpose programming language to read raw event data, group the event data by user identifier and session identifier, and compute feature values such as click counts for each element identifier, average scrolling speed per screen, session lengths, and frequencies of access to particular categories.

The server converts such computed feature values into input vectors to the information processing model. In one embodiment, the information processing model is a feed-forward neural network implemented in a deep learning framework. The neural network includes an input layer whose dimensionality corresponds to the number of feature values, one or more hidden layers with rectified linear unit activation functions, and an output layer generating one or more user behavior indices such as a predicted click-through probability, a predicted conversion rate, or a predicted session duration. The server normalizes the feature values using predetermined scaling parameters and supplies the normalized features to the neural network. The server then receives numerical outputs and stores the user behavior indices in association with the corresponding user identifiers and sessions.

The server also acquires emotion-related data from the terminal. The terminal captures images of the user's face using the camera and captures audio representing the user's voice using the microphone. The terminal associates each captured frame or audio segment with a timestamp and a session identifier, and transmits the data to the server. In another embodiment, the terminal performs preliminary processing such as face detection and audio clipping and transmits only cropped images and trimmed audio segments.

The server executes an emotion recognition model to identify user emotion states from the emotion-related data. In one embodiment, the server uses a convolutional neural network trained on facial expression images. The convolutional neural network includes multiple convolutional layers, pooling layers, and fully connected layers, and outputs class probabilities over predefined emotion categories such as stress, confusion, joy, curiosity, and neutrality. The server feeds cropped facial images into this network and interprets the highest probability class as the facial emotion. For the audio data, the server applies a speech recognition process to obtain text, and then applies a text-based sentiment classifier such as a bidirectional transformer network to infer emotional tone. The server then combines the facial emotion and the textual emotion by computing a weighted average of class probabilities or by executing a separate fusion network. The result is stored as a user emotion state with a confidence value in the storage resource.

The server constructs context information by associating user behavior indices and user emotion states for the same user and session. The context information includes at least a numerical representation of user behavior tendencies and a categorical representation of the current emotion state. Optionally, the context information further includes a task type, a device type, and a current screen identifier. The server uses this context information to generate prompt sentences for a generative AI model.

The server maintains a prompt generation module that uses rule-based templates and, in some embodiments, a smaller language model to convert internal structured data into natural language prompt sentences. The server inserts numerical values, categories, and additional constraints into pre-defined textual patterns so that the generative AI model receives machine-interpretable instructions. For example, in response to detecting that the user frequently accesses a particular category and is currently stressed, the server may generate a prompt sentence such as:

“The user frequently accesses the e-book category and is currently showing signs of stress based on emotion recognition. Propose a simplified user interface layout that places the e-book category at the top of the home screen and highlights a single primary purchase button, and explain briefly why this layout reduces cognitive load.”

The server transmits such a prompt sentence to the generative AI model through a model interface. In one embodiment, the generative AI model is a transformer-based language model that receives the prompt as a sequence of tokens and generates a textual response token by token, using self-attention layers and a beam search or sampling algorithm. The server sets decoding parameters such as temperature, maximum token length, and top-k or top-p thresholds to control diversity and determinism.

The generative AI model outputs a response that may include a description of a screen configuration modification proposal or an information presentation method. To avoid reliance on unstructured text only, the server instructs the generative AI model, via the prompt sentence, to output information in a semi-structured textual form (for example, naming element identifiers and positions explicitly). The server then parses the generated text using deterministic patterns or a lightweight parser to extract structured layout information. The structured layout information includes element identifiers, coordinates, sizes, visibility flags, and other attributes that a rendering engine on the terminal understands. The server sends this structured layout information to the terminal, and the terminal updates the user interface accordingly. Through this mechanism, the server does not simply replace human design work but enables a new interaction pattern where latent model knowledge is transformed into device-ready layout instructions.

The server also generates prompt sentences to instruct analysis of design elements and application of prediction computation processing. For example, when a user edits a design using a design tool, the terminal sends design change content to the server in a structured manner. The server encodes design elements such as colors, font sizes, spacing, and element counts into feature vectors and feeds the vectors into a prediction computation model, such as a neural network trained to predict expected engagement changes. In parallel, the server generates a prompt sentence such as:

“Based on the following design characteristics (color contrast, font size, number of clickable elements, depth of navigation), analyze the design and describe how these elements are likely to affect user engagement and clarity.”

By making the generative AI model work on numerically informed descriptions, the server improves the interpretability and reliability of AI-generated explanations, and the computer system gains an internal, machine-driven mechanism for mapping low-level design parameters to higher-level design feedback without human intervention.

In another embodiment, the server generates prompt sentences for instructing collection and evaluation of operation histories to perform usability evaluation processing. After monitoring the operation history for a given time window, the server creates an aggregated representation of the interaction patterns and constructs a prompt sentence such as:

“Using the following summary of user operations (frequent backtracking, long dwell time on form pages, high abandonment rate on the checkout screen), evaluate the usability of the interface and identify the three most critical usability issues, with specific references to the operation patterns.”

This approach allows the server to systematically transform low-level logs into high-level usability diagnoses while reducing the number of custom analytic programs the system must maintain. Because this prompt generation runs entirely on the server using structured data and standard templates, the process reduces engineering complexity and enables the computer to manage different analysis tasks using a unified generative AI interface.

The server further generates prompt sentences for instructing analysis of design change content and evaluation of an influence caused by the design change content. For example, the server may generate:

“Given the described design changes (moving the main call-to-action button from the bottom to the center, simplifying the navigation menu, increasing font size on product titles), evaluate the predicted impact on conversion rate, time to complete purchase, and error rate, using the historical behavior data and prediction model outputs.”

The generative AI model, operating on this prompt, returns a detailed evaluation, which is then interpreted by the server and stored alongside quantitative predictions.

The server also supports simulated qualitative evaluation processing. In one embodiment, the server stores templates describing virtual user attributes such as “older novice user,” “expert frequent buyer,” or “mobile-only user in a low-bandwidth environment.” When the server needs qualitative feedback, the server generates evaluation scenarios and corresponding prompt sentences that instruct the generative AI model to respond as if it were each virtual user. An example prompt sentence is:

“You are a 55-year-old user with limited technical experience who primarily uses a smartphone. You are using the following checkout flow: [flow description]. Describe your feelings, difficulties, and expectations during this process, and suggest what would make the interface easier for you.”

The server collects multiple such responses, analyzes them, and extracts insights using additional prompt sentences that ask the generative AI model to summarize recurring issues and opportunities. These simulated evaluations allow the computer system to explore a large space of user perspectives without requiring separate, human-conducted sessions, and the insight extraction is integrated into the same prompt-based orchestration framework.

In yet another embodiment, the server integrates quantitative evaluation results and insights into report information understandable to the user. The server aggregates numerical metrics from the prediction models and summarized insights from qualitative evaluations. The server then generates a prompt sentence such as:

“Create a concise report for a product designer summarizing (1) the predicted quantitative impact of the recent UI changes on conversion and abandonment, and (2) the key usability issues and improvement suggestions derived from simulated user feedback. Use clear section headings and short bullet points.”

The generative AI model returns a structured report narrative, which the server converts into a document format, such as a portable document format or a web page, and stores or transmits to the terminal. Through this integrated pipeline, the server reduces manual reporting workload and provides consistent, machine-generated documentation.

These embodiments improve computer technology in several ways. First, because the server generates prompt sentences automatically from structured internal state, the system reduces the risk of human error in prompt construction and reduces variability in AI outputs. This leads to more predictable responses and allows cache reuse for similar contexts, thereby reducing communication overhead with the generative AI model provider. Second, the use of standardized structured layout information enables the terminal's rendering engine to apply layout changes without complex custom parsing, reducing CPU usage on the terminal and allowing near real-time UI adaptation. Third, by combining prediction models and emotion recognition models inside the server, and by coordinating their outputs through explicit data structures, the system avoids redundant computations and improves data locality, which in turn reduces memory pressure and processing time.

In contrast to conventional systems that simply automate human design tasks, the described system introduces a non-conventional architecture in which internal usage features, emotion states, and design parameters are systematically converted into prompt sentences and structured outputs, with a feedback loop that retrains models based on realized performance. During training, the server uses supervised learning with labeled behavior and emotion data, applies a loss function such as cross-entropy for classification or mean squared error for regression, and updates model weights using stochastic gradient descent with adaptive learning rates. The server may also apply data augmentation techniques for emotion recognition, such as random cropping, rotation, or audio perturbation, to increase robustness. These training processes allow the server to maintain high prediction accuracy and to adapt to new usage patterns, improving the overall fidelity and responsiveness of the system.

In one variation, the server executes the information processing model on a specialized accelerator such as a graphics processing unit, and schedules model inference tasks through a queue manager to guarantee throughput for concurrent sessions. In another variation, the terminal performs a subset of the feature extraction and emotion recognition using on-device models, and only transmits intermediate representations to the server, thereby reducing network bandwidth usage and enhancing privacy. In yet another variation, the server employs different generative AI models for different tasks, such as one model optimized for layout recommendation and another model optimized for narrative report generation, and selects a model based on the content of the prompt sentence.

Through these various embodiments and alternatives, the server, the terminal, and the user cooperate to implement a system in which a generative AI model is invoked through well-defined prompt sentences derived from internal machine-readable state, and in which the outputs of such models are transformed into structured layout information and report information that directly control the operation of display hardware and data storage structures. As a result, the system does not merely automate business logic but improves the operation of the computing infrastructure itself by reducing latency, increasing prediction and adaptation accuracy, lowering communication overhead, and enabling dynamic, fine-grained control of user interface rendering and information presentation.

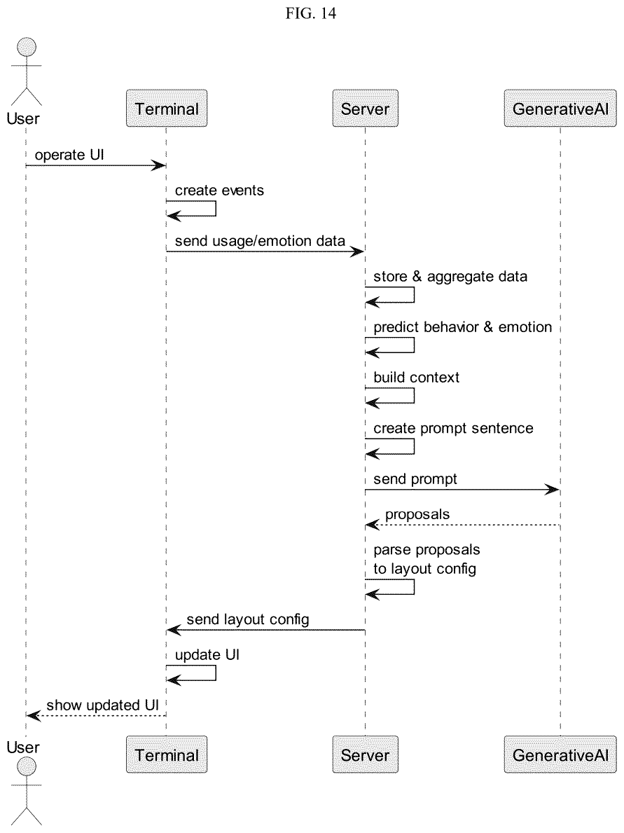

The following describes the processing flow using FIG. 14.

### Step 1

User operates the application on the terminal.

User taps buttons, scrolls content, switches screens, and enters text such as search queries or natural-language requests.

Input: No digital input is required other than the user's physical interactions with the display and input devices.

Output: Terminal generates raw interaction events representing user operations.

### Step 2

Terminal records usage data as structured event objects.

Terminal creates, for each detected interaction, an event object including at least a user identifier, a session identifier, an event type (for example, “click”, “scroll”, “view”, “input”), a timestamp, an element identifier, and additional parameters such as scroll distance or input length.

Terminal stores the event objects temporarily in a local buffer or queue.

Input: Low-level signals from the touch panel, keyboard, pointing device, and system UI callbacks.

Output: A sequence of structured event objects queued for transmission.

### Step 3

Terminal transmits batched usage data to the server.

Terminal periodically reads the buffered event objects, groups them into a batch up to a predefined size or time interval, and serializes the batch into a structured payload.

Terminal sends the payload to the server via a communication interface using a request message over a network protocol.

Input: The buffered sequence of structured event objects.

Output: A network message containing a batch of usage data delivered to the server.

### Step 4

Server receives and validates usage data.

Server parses the incoming payload, verifies authentication tokens, and checks the schema of each event object.

Server discards malformed events and flags invalid sessions, then prepares a clean set of event records.

Input: The serialized batch of usage data sent by the terminal.

Output: A validated list of event records suitable for storage and further processing.

### Step 5

Server stores usage data in a storage resource.

Server writes each validated event record as a row into one or more tables of a database, such as a user event table and a session table.

Server indexes relevant columns (user identifier, session identifier, timestamp, element identifier) to support efficient queries.

Input: The validated list of event records.

Output: Persisted usage data stored in database tables, accessible for aggregation and analysis.

### Step 6

Server aggregates usage data and computes feature values.

Server executes a data processing program that reads recent event records, groups them by user identifier and session identifier, and computes statistics such as counts of clicks per element, average scroll velocity, dwell time per screen, and frequencies of access to content categories.

Server converts these statistics into numerical or categorical feature values and stores them in a feature table.

Input: Raw event records retrieved from the database.

Output: Feature vectors representing usage tendencies for users and sessions.

### Step 7

Server predicts user behavior indices using an information processing model.

Server normalizes feature values using stored scaling parameters and feeds the normalized vectors into a prediction model, such as a neural network.

Server obtains output values corresponding to user behavior indices (for example, predicted conversion rate, predicted session duration, or probability of clicking a target element) and stores the indices with references to the original sessions.

Input: Feature vectors representing usage tendencies.

Output: Predicted user behavior indices associated with users and sessions.

### Step 8

Terminal captures emotion-related data.

Terminal uses an integrated camera to capture facial images and a microphone to capture audio segments while the application is active, associating each capture with a timestamp and session identifier.

Terminal optionally performs basic preprocessing such as resizing the images or trimming silence from audio.

Input: Physical signals from the camera sensor and microphone.

Output: Captured image data and audio data segments tagged with user and session information.

### Step 9

Terminal sends emotion-related data to the server.

Terminal packs the preprocessed images and audio segments into a structured payload and includes references to the corresponding session identifiers.

Terminal transmits this payload to the server over the network using a defined endpoint for emotion data.

Input: Captured and optionally preprocessed emotion-related data.

Output: A network message containing emotion-related data delivered to the server.

### Step 10

Server identifies user emotion states from emotion-related data.

Server applies a face detection algorithm to the received image data, crops the face region, and inputs the cropped images into an emotion recognition model, such as a convolutional neural network.

Server applies a speech-to-text process to the audio data to obtain textual transcripts and feeds the transcripts into a text-based sentiment classifier.

Server combines visual and textual predictions to determine a user emotion state (for example, stress, confusion, joy, curiosity, neutrality) and computes a confidence score.

Server stores the emotion state in association with the corresponding user identifier, session identifier, and time range.

Input: Cropped facial images and audio-derived text transcripts.

Output: User emotion states with confidence values stored in the database.

### Step 11

Server constructs context information.

Server retrieves user behavior indices and emotion states for a particular session and merges them into a single context object that also contains optional attributes such as task type, device type, and current screen identifier.

Server encodes this context information as a structured internal representation used by downstream modules.

Input: Predicted user behavior indices and stored user emotion states.

Output: A context object containing combined behavioral and emotional information.

### Step 12

Server generates a prompt sentence for a generative AI model based on context information.

Server selects a prompt template according to the context type (for example, UI optimization, usability evaluation, campaign evaluation) and fills placeholders in the template with values from the context object.

Server produces a natural-language prompt sentence that specifies both the task and the relevant data, such as behavior indices and emotion states.

Input: Context object including user behavior indices, user emotion states, and optional attributes.

Output: A concrete prompt sentence instructing the generative AI model what to generate.

### Step 13

Server transmits the prompt sentence to the generative AI model and receives output proposals.

Server sends the generated prompt sentence to a generative AI model interface and configures decoding parameters such as maximum output length and randomness.

Server waits for the model to generate a textual response containing a screen configuration modification proposal or an information presentation method.

Input: The prompt sentence created from context information.

Output: A textual response containing one or more output proposals generated by the generative AI model.

### Step 14

Server converts output proposals into structured layout information.

Server analyzes the textual response, extracts references to interface elements, positions, visibility instructions, and presentation details using deterministic parsing rules or a lightweight classifier.

Server maps these extracted values to a machine-readable layout schema, generating structured layout information that specifies concrete coordinates, sizes, and properties of UI components.

Input: textual output proposals produced by the generative AI model.

Output: Structured layout information suitable for direct consumption by a rendering engine on the terminal.

### Step 15

Server sends structured layout information to the terminal.

Server packages the structured layout information as a response to a configuration request or as a push message and transmits it over the network to the terminal.

Server may also include metadata such as version identifiers and validity periods for the configuration.

Input: Structured layout information generated from the model's output.

Output: A network message containing layout configuration data received by the terminal.

### Step 16

Terminal updates the user interface according to the structured layout information.

Terminal parses the received layout configuration and maps layout attributes to the corresponding visual components in its user interface framework.

Terminal rearranges UI elements, changes their visibility, adjusts sizes, and updates labels or styles to match the configuration, and then re-renders the display screen.

Input: Structured layout configuration data sent by the server.

Output: An updated display screen presented to the user with a modified screen configuration.

### Step 17

Server generates additional prompt sentences for design and usability analysis.

Server retrieves design element data, operation histories, and prediction outputs, and forms specific prompts to request analysis of design elements, usability issues, or design change impacts.

Server produces prompt sentences such as design analysis requests, usability evaluations, and impact assessments, each incorporating structured metrics and descriptions.

Input: Design element representations, aggregated operation histories, and prediction computation results.

Output: Additional prompt sentences tailored to analytic tasks for the generative AI model.

### Step 18

Server performs simulated qualitative evaluation processing using prompt sentences.

Server generates evaluation scenarios with virtual user attributes and attaches them to prompt sentences addressed to the generative AI model, instructing the model to respond as if it were each virtual user.

Server collects the generated responses as a response information group and may further generate meta-prompts requesting the generative AI model to extract insights from this group.

Input: Evaluation scenarios including virtual user attributes and question contents, and corresponding prompt sentences.

Output: Simulated qualitative responses and extracted insights describing recurring issues and improvement opportunities.

### Step 19

Server integrates quantitative evaluation results and insights into report information.

Server combines numerical outputs from prediction computation processing and qualitative insights from simulated evaluations into a unified data structure.

Server generates a prompt sentence instructing the generative AI model to create a human-readable report using the unified data, then receives and stores the generated report text.

Input: Quantitative evaluation results and extracted insights.

Output: Report information in textual form, which can be further converted into a document or displayed to the user.

### Step 20

User views optimized interfaces and generated reports on the terminal.

User interacts with the dynamically adapted user interface and accesses generated reports through application screens.

Input: Updated UI rendered according to structured layout information and report information delivered from the server.

Output: Additional user interactions and feedback, which are again captured as usage data and fed back into the processing flow.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Moreover, although the processing by the data processing system 10 described above was executed by the specific processing unit 290 of the data processing device 12 or by the control unit 46A of the smart device 14, the processing may be executed by a specific processing unit 290 of the data processing device 12 and a control unit 46A of the smart device 14. Moreover, the specific processing unit 290 of the data processing device 12 acquires and collects information needed for processing from the smart device 14 or from an external device or the like, and the smart device 14 acquires and collects information needed for processing from the data processing device 12 or from an external device or the like.

For example, a collection unit is implemented by the control unit 46A of the smart device 14 and/or by the specific processing unit 290 of the data processing device 12. For example, an acquisition unit acquires number-of-steps data using the camera 42 and/or the communication I/F 44 of the smart device 14, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the output device 40 of the smart device 14 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the smart device 14.

### Second Exemplary Embodiment

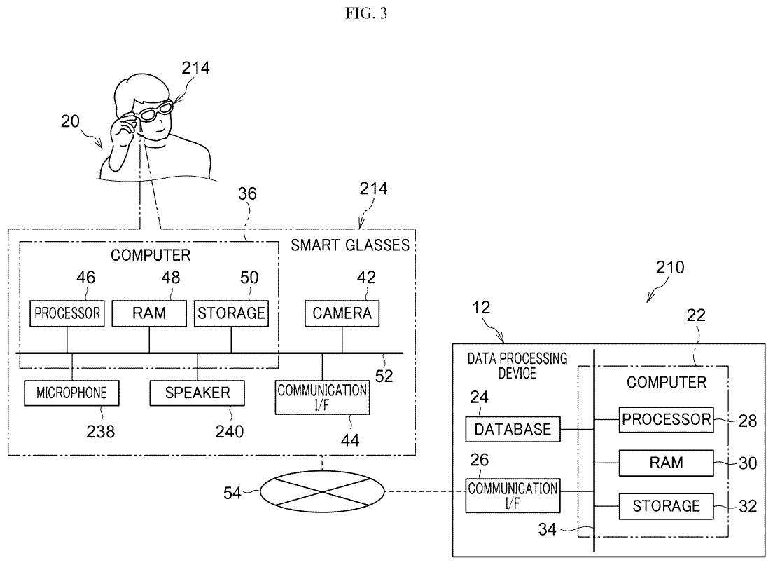

FIG. 3 illustrates an example of a configuration of a data processing system 210 according to a second exemplary embodiment.

As illustrated in FIG. 3, the data processing system 210 includes a data processing device 12 and smart glasses 214. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The smart glasses 214 include a computer 36, a microphone 238, a speaker 240, a camera 42, and a communication I/F 44. The computer 36 includes a processor 46, RAM 48, and storage 50. The processor 46, the RAM 48, and the storage 50 are connected to a bus 52. The microphone 238, the speaker 240, the camera 42, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the user 20 (for example, an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

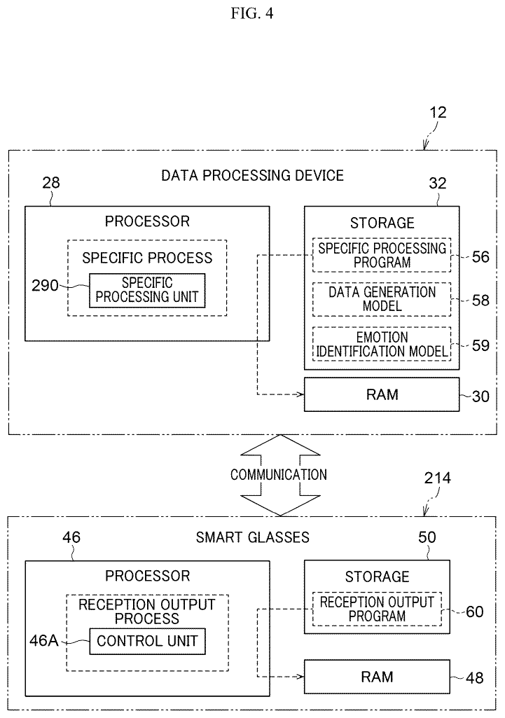

FIG. 4 illustrates an example of relevant functions of the data processing device 12 and the smart glasses 214. As illustrated in FIG. 4, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290. The specific processing unit 290 uses the emotion identification model 59 to estimate an emotion of a user, and is able to perform the specific processing using the user emotion. In an emotion estimation function (emotion identification function) that uses the emotion identification model 59, various estimations, predictions, and the like are performed related to emotions of the user, include estimating and predicting the emotion of the user, however, there is no limitation to such examples. Moreover, estimation and prediction of emotion also includes, for example, analyzing (parsing) emotions and the like.

Reception and output processing is performed by the processor 46 in the smart glasses 214. A reception and output program 60 is stored in the storage 50. The processor 46 reads the reception and output program 60 from the storage 50 and in the RAM 48 executes the read reception and output program 60. The reception and output processing is implemented by the processor 46 operating as the control unit 46A according to the reception and output program 60 executed in the RAM 48. Note that a configuration may be adopted in which the smart glasses 214 include a data generation model and an emotion identification model similar to the data generation model 58 and the emotion identification model 59, and processing similar to the specific processing unit 290 is performed using these models.

Next, description follows regarding the specific processing by the specific processing unit 290 of the data processing device 12. The units of the system described below are implemented by the data processing device 12 and the smart glasses 214. In the following description the data processing device 12 is called a “server”, and the smart glasses 214 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the smart glasses 214. The control unit 46A in the smart glasses 214 outputs the specific processing result to the speaker 240. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the smart glasses 214, the processing may be executed by a specific processing unit 290 of the data processing device 12 and a control unit 46A of the smart glasses 214. Moreover, the specific processing unit 290 of the data processing device 12 acquires and collects information needed for processing from the smart glasses 214 or from an external device or the like, and the smart glasses 214 acquires and collects information needed for processing from the data processing device 12 or from an external device or the like.

For example, the collection unit is implemented by the control unit 46A of the smart glasses 214 and/or by the specific processing unit 290 of the data processing device 12. For example, an acquisition unit acquires number-of-steps data using the camera 42 and/or the communication I/F 44 of the smart glasses 214, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 of the smart glasses 214 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the smart glasses 214.

### Third Exemplary Embodiment

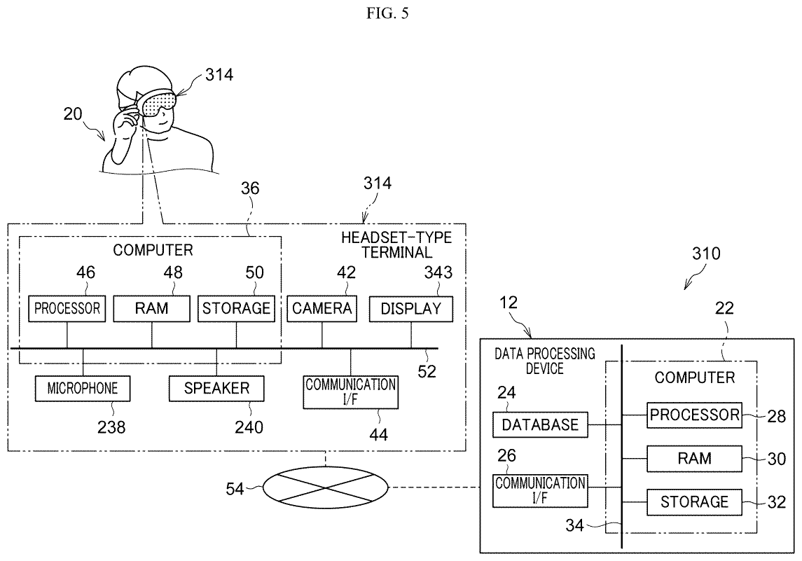

FIG. 5 illustrates an example of a configuration of a data processing system 310 according to a third exemplary embodiment.

As illustrated in FIG. 5, the data processing system 310 includes a data processing device 12 and a headset-type terminal 314. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The headset-type terminal 314 includes a computer 36, a microphone 238, a speaker 240, a camera 42, a communication I/F 44, and a display 343. The computer 36 includes a processor 46, RAM 48, and storage 50. The processor 46, the RAM 48, and the storage 50 are connected to a bus 52. The microphone 238, the speaker 240, the camera 42, the display 343, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the user 20 (for example, an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

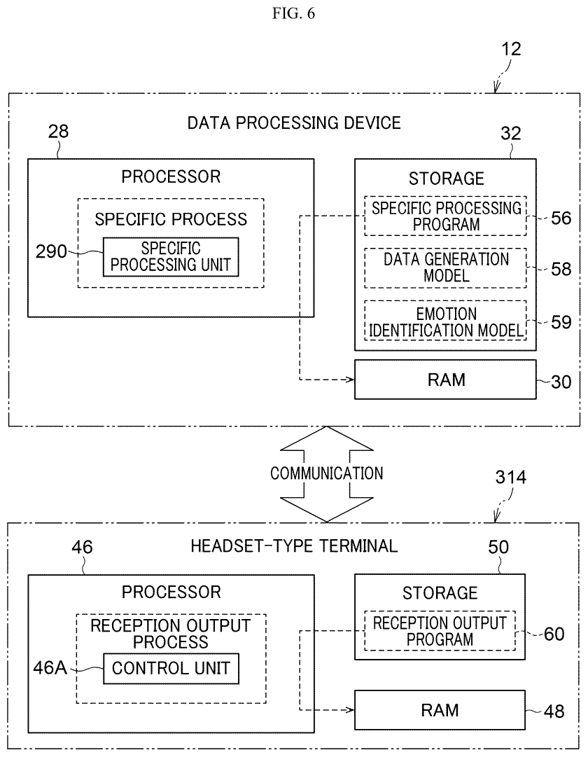

FIG. 6 illustrates an example of relevant functions of the data processing device 12 and the headset-type terminal 314. As illustrated in FIG. 6, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290.

Reception and output processing is performed by the processor 46 in the headset-type terminal 314. A reception and output program 60 is stored in the storage 50. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48.

Next, description follows regarding the specific processing by the specific processing unit 290 of the data processing device 12. The units of the system described below are implemented by the data processing device 12 and the headset-type terminal 314. In the following description the data processing device 12 is called a “server”, and the headset-type terminal 314 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the headset-type terminal 314. In the headset-type terminal 314, the control unit 46A outputs the result of the specific processing to the speaker 240 and the display 343. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the headset-type terminal 314, the processing may be executed by a specific processing unit 290 of the data processing device 12 and a control unit 46A of the headset-type terminal 314. Moreover, the specific processing unit 290 of the data processing device 12 acquires and collects information needed for processing from the headset-type terminal 314 or from an external device or the like, and the headset-type terminal 314 acquires and collects information needed for processing from the data processing device 12 or from an external device or the like.

For example, the collection unit is implemented by the control unit 46A of the headset-type terminal 314 and/or by the specific processing unit 290 of the data processing device 12. For example, an acquisition unit acquires number-of-steps data using the camera 42 and/or the communication I/F 44 of the headset-type terminal 314, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 and the display 343 of the headset-type terminal 314 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the headset-type terminal 314.

### Fourth Exemplary Embodiment

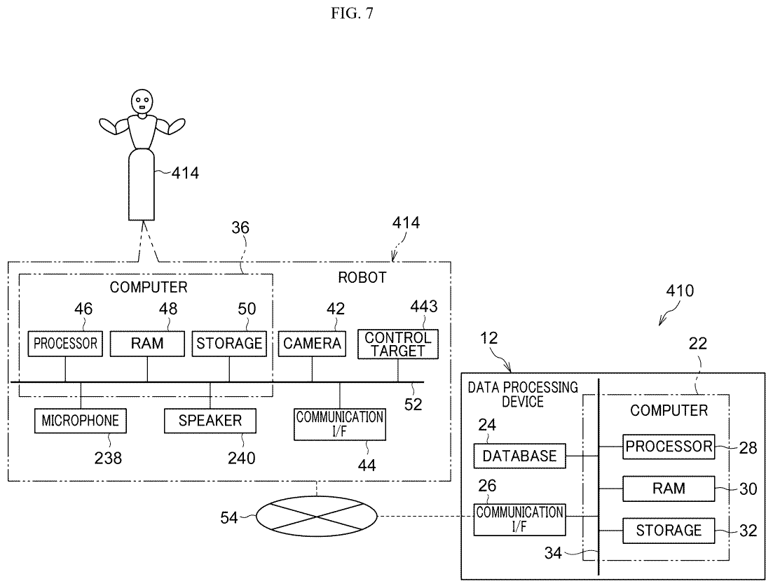

FIG. 7 illustrates an example of a configuration of a data processing system 410 according to a fourth exemplary embodiment

As illustrated in FIG. 7, the data processing system 410 includes a data processing device 12 and a robot 414. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The robot 414 includes a computer 36, a microphone 238, a speaker 240, a camera 42, a communication I/F 44, and a control target 443. The computer 36 includes a processor 46, RAM 48, and storage 50. The processor 46, the RAM 48, and the storage 50 are connected to a bus 52. The microphone 238, the speaker 240, the camera 42, the control target 443, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the robot 414 (for example, with an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

The control target 443 includes a display device, eye LEDs, and motors to drive arms, hands, feet, and the like. The posture and gesture of the robot 414 are controlled by controlling the motors of the arms, hands, feet, and the like. Part of an emotion of the robot 414 can be expressed by controlling these motors. Moreover, a facial expression of the robot 414 can be represented by controlling an illumination state of the eye LEDs of the robot 414.

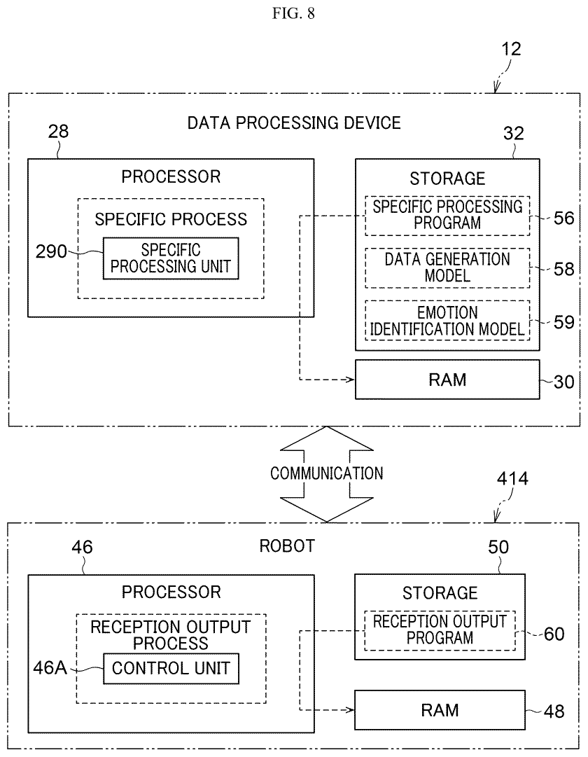

FIG. 8 illustrates an example of relevant functions of the data processing device 12 and the robot 414. As illustrated in FIG. 8, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290.

Reception and output processing is performed by the processor 46 in the robot 414. A reception and output program 60 is stored in the storage 50. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48.

Next, description follows regarding the specific processing by the specific processing unit 290 of the data processing device 12. The units of the system described below are implemented by the data processing device 12 and the robot 414. In the following description the data processing device 12 is called a “server”, and the robot 414 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the robot 414. In the robot 414, the control unit 46A outputs the result of the specific processing to the speaker 240 and the control target 443. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the robot 414, the processing may be executed by a specific processing unit 290 of the data processing device 12 and a control unit 46A of the robot 414. Moreover, the specific processing unit 290 of the data processing device 12 acquires and collects information needed for processing from the robot 414 or from an external device or the like, and the robot 414 acquires and collects information needed for processing from the data processing device 12 or from an external device or the like.

For example, the collection unit is implemented by the control unit 46A of the robot 414 and/or by the specific processing unit 290 of the data processing device 12. For example, an acquisition unit acquires number-of-steps data using the camera 42 and/or the communication I/F 44 of the robot 414, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 and the control target 443 of the robot 414 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the robot 414.

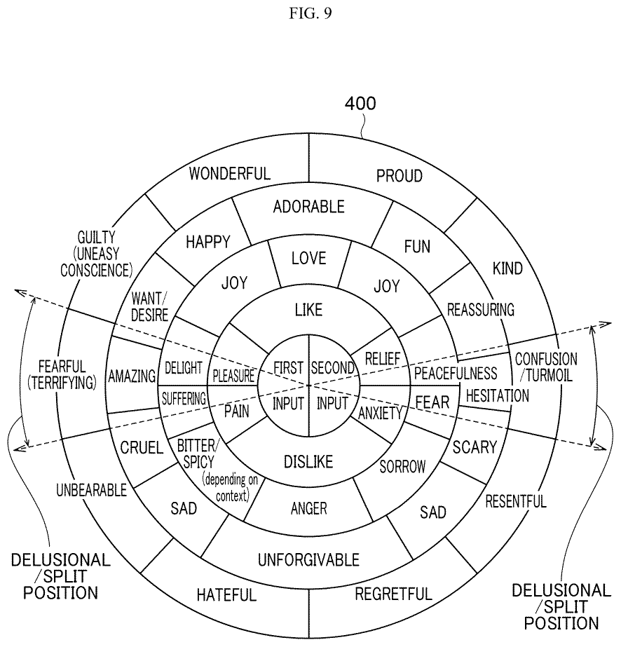

Note that the emotion identification model 59 serves as an emotion engine, and may decide the emotion of a user according to a specific mapping. Specifically, the emotion identification model 59 may decide the emotion of a user according to an emotion map (see FIG. 9) that is a specific mapping. Moreover, the emotion identification model 59 may also decide the emotion of the robot similarly, and the specific processing unit 290 may be configured so as to perform the specific processing using the emotion of the robot.

FIG. 9 is a diagram illustrating an emotion map 400 mapping plural emotions. In the emotion map 400, emotions are arranged in concentric circles that radiate out from the center. Primitive states of emotion are arranged nearer to the center of the concentric circles. Emotions expressing states and actions generated from states of mind are arranged further toward the outside of the concentric circles. Emotions are defined as including both affect and mental states. Emotions generated from reactions occurring in the brain are generally arranged at the left side of the concentric circles. Emotions induced by situational assessment are generally arranged at the right side of the concentric circles. Emotions generated from reactions occurring in the brain that are also emotions induced by situational assessment are generally arranged toward the top and toward the bottom of the concentric circles. Moreover, emotions of “euphoria” are arranged at the upper side of the concentric circles, and emotions of “dysphoria” are arranged at the lower side of the concentric circles. Plural emotions are accordingly mapped in this manner in the emotion map 400 based on a structure giving rise to emotions, and emotions that readily occur at the same time are mapped close to each other.

An example of such emotions is a distribution of emotions in the direction of 3 o'clock on the emotion map 400, generally around a boundary between relief and anxiety. Situational awareness dominates over internal sensations in the right half of the emotion map 400, with an impression of calm.

The inside of the emotion map 400 represents feelings, and the outside of the emotion map 400 represents actions, and so emotions further toward the outside of the emotion map 400 are more visible (are expressed by actions).

Human emotions are based on various balances, such as posture and blood sugar value balances, with a state of dysphoria being exhibited when these balances are far from ideal and a state of euphoria being exhibited when these balances are near to ideal. Even in a robot, a car, a motorbike, or the like, emotions can be thought of as being based on various balances such as orientation and remaining battery balances, with a state called dysphoria being exhibited when these balances are far from ideal and a state called euphoria being exhibited when these balances are near to ideal. An emotion map may, for example, be generated based on the emotion map of Dr. Mitsuyoshi (PhD Dissertation https://ci.nii.ac.jp/naid/500000375379: “Research on the phonetic recognition of feelings and a system for emotional physiological brain signal analysis”, Tokushima University). Emotions belonging to an area called “reaction” where feeling dominates are arranged in the left half of the emotion map. Moreover, emotions belonging to an area called “situation” where situational awareness dominates are arranged in the right half of the emotion map.

There are two types of emotion that facilitate leaning in an emotion map. One is an emotion in the vicinity of the center of negative “penitence” and “reflection” on the situational side. In other words, sometimes a negative “emotion” such as “I don't want to feel this way ever again” and “I don't want to be chided again” is experienced in a robot. Another is a positive emotion in the area of “desire” on the reaction side. In other words, there are times when a positive feeling such as “desire more” and “want to know more” is experienced.

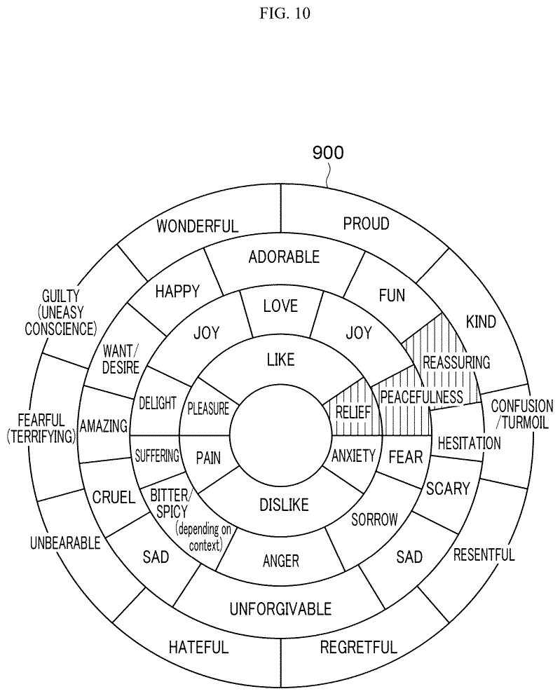

In the emotion identification model 59, user input is input to a pre-trained neural network, and emotion values indicating emotions shown on the emotion map 400 are acquired and the emotions of the user are decided. This neural network is pre-trained based on plural training data sets that each combine a user input with an emotion value indicating an emotion shown on the emotion map 400. The neural network is also trained such that emotions arranged close to each other have values that are close to each other, as in an emotion map 900 illustrated in FIG. 10. In FIG. 10 the plural emotions of “relief”, “peaceful”, and “reassured” are indicated as an example of close emotion values.

Although the system according to the present disclosure has been described mainly as functions of the data processing device 12, the system according to the present disclosure is not limited to being implemented in a server. The system according to the present disclosure may be implemented as a general information processing system. The present disclosure may, for example, be implemented by a software program operating on a personal computer, and may be implemented by an application operating on a smartphone or the like. The method according to the present disclosure may also be supplied to a user in the form of Software as a Service (SaaS).

Although in the exemplary embodiments described above examples are given of embodiments in which the specific processing is performed by a single computer 22, technology disclosed herein is not limited thereto, and distributed processing may be performed for the specific processing, with the specific processing distributed across plural computers including the computer 22. For example, the data generation model 58 may be provided in a device external to the data processing device 12, such that data generation in response to input data is performed in the external device.

Although in the exemplary embodiments described above examples are described of embodiments in which the specific processing program 56 is stored in the storage 32, the technology disclosed herein is not limited thereto. For example, the specific processing program 56 may be stored on a portable, non-transitory, computer readable, storage medium, such as universal serial bus (USB) memory or the like. The specific processing program 56 stored on the non-transitory storage medium is then installed on the computer 22 of the data processing device 12. The processor 28 then executes the specific processing according to the specific processing program 56.

Moreover, the specific processing program 56 may be stored on a storage device, such as a server connected to the data processing device 12 over the network 54, with the specific processing program 56 then being downloaded in response to a request from the data processing device 12 and installed on the computer 22.

Note that there is no need to store the entire specific processing program 56 on the storage device, such as a server connected to the data processing device 12 over the network 54, or to store the entire specific processing program 56 on the storage 32, and part of the specific processing program 56 may be stored thereon.

Hardware resources for executing the specific processing may use various processors as listed below. Examples of processors include, for example, a CPU that is a general-purpose processor that functions as a hardware resource to execute the specific processing by executing software, namely a program. Moreover, the processor may, for example, be a dedicated electronic circuit that is a processor having a circuit configuration custom designed for executing the specific processing, such as a field-programmable gate array (FPGA), a programmable logic device (PLD), or an application specific integrated circuit (ASIC). Memory is inbuilt or connected to each of these processors, and the specific processing is executed by each of these processors using the memory.

The hardware resource that executes the specific processing may be configured from one of these various processors, or may be configured from a combination of two or more processors of the same or different type (for example, a combination of plural FPGAs, or a combination of a CPU and a FPGA). The hardware resource executing the specific processing may be a single processor.

Examples of configurations of a single processor include, firstly, a configuration of a single processor resulting from combining one or more CPU and software, in an embodiment in which this processor functions as the hardware resource for executing the specific processing. Secondly, as typified by a System-on-chip (SOC) or the like, there is also an embodiment that uses a processor realized by a single IC chip to function as an overall system including plural hardware resources for executing the specific processing. Adopting such an approach means that the specific processing is realized using one or more of the various processors described above as hardware resource.

Furthermore, more specifically, an electrical circuit that combines circuit elements such as semiconductor elements or the like may be employed as a hardware structure of these various processors. The specific processing is merely an example thereof. This means that obviously redundant steps may be omitted, new steps may be added, and the processing sequence may be swapped around within a range not departing from the spirit of the present disclosure.

The described content and drawing content illustrated above are a detailed description of parts according to the present disclosure, and are merely examples of the present disclosure. For example, description related to the above configuration, function, operation, and advantageous effects is a description related to examples of the configuration, function, operation, and advantageous effects of parts according to the present disclosure. This means that obviously redundant parts may be eliminated, new elements may be added, and switching around may be performed on the described content and drawing content illustrated above within a range not departing from the spirit of the present disclosure. Moreover, to avoid misunderstanding and to facilitate understanding of parts according to the present disclosure, description related to common knowledge in the art and the like not particularly needing description to enable implementation of the present disclosure is omitted in the described content and drawing content illustrated as described above.

All publications, patent applications and technical standards mentioned in the present specification are incorporated by reference in the present specification to the same extent as if each individual publication, patent application, or technical standard was specifically and individually indicated to be incorporated by reference.

Note that, regarding the above description, the following supplementary notes are further disclosed.

### Example 1

### Supplementary 1

A system comprising a processor,
wherein the processor is configured to
receive, from a terminal via a communication network, screen configuration information and operation information, and generate design change information that abstractly represents display elements and layout elements included in an information processing screen to be displayed, based on the screen configuration information and the operation information, generate, based on the design change information and user attribute information, a prompt sentence in a natural language, the prompt sentence including a predetermined sentence structure and an output format specification, the prompt sentence being configured to cause a generative artificial intelligence model to execute prediction of quantitative evaluation values including behavior indicators and performance indicators,
transmit the prompt sentence to the generative artificial intelligence model via the communication network and acquire a prediction result including the quantitative evaluation values from the generative artificial intelligence model,
extract the quantitative evaluation values from the prediction result, normalize the quantitative evaluation values as evaluation data associated with the design change information, and generate quantitative report information indicating an effect of the design change and explanatory text information explaining the quantitative report information, based on the evaluation data, and
output presentation control information configured to cause the terminal to display the quantitative report information and the explanatory text information in a form that is traceable in time series.

### Supplementary 2

The system according to supplementary 1,
wherein the processor is configured to
generate interview setting information including a plurality of user types and usage situations based on the design change information and the quantitative evaluation values, generate a prompt sentence configured to cause the generative artificial intelligence model to execute a simulated qualitative interview in accordance with the interview setting information, analyze qualitative response information acquired from the generative artificial intelligence model, and cause the terminal to present qualitative evaluation information associated with the quantitative report information.

### Supplementary 3

The system according to supplementary 1,
wherein the processor is configured to
select extraction conditions for extracting predetermined indicator values and explanatory elements from the prediction result according to an expression format of the prediction result returned by the generative artificial intelligence model, convert the prediction result into a machine-readable internal data structure based on the extraction conditions, and generate, based on the internal data structure, a prompt sentence or presentation control information for generating presentation content in a format understandable to a user.

### Application Example 1

### Supplementary 1

A system comprising a processor,
wherein the processor is configured to
receive, from a terminal device, design change information including a plurality of presentation elements of a display and corresponding change contents, and analyze the plurality of presentation elements and the change contents,
acquire, from a storage device, past change history information corresponding to the design change information and behavior history information related to user behavior, and associate the past change history information with the behavior history information to construct learning input information,
perform preprocessing on the learning input information, the preprocessing including quantization processing and normalization processing, to generate feature data for numerical computation processing,
generate a prompt sentence for input into a generative artificial intelligence model, the prompt sentence being based on the feature data and the design change information,
input the feature data into a trained prediction model executed on a numerical computation device, and calculate predicted values of indicators including click-through rate, conversion rate, and revenue-related indicators as numerical prediction processing,
input the prompt sentence and the predicted values of the indicators into the generative artificial intelligence model, and cause the generative artificial intelligence model to generate a natural language response including qualitative insights and improvement proposals regarding an influence of the design change on user behavior and business indicators,
analyze the predicted values of the indicators and the natural language response, and generate feedback information including quantitative evaluation information indicating an effect of the design change and a plurality of improvement options related to the design change,
format the feedback information into a predetermined data structure, transmit the formatted feedback information to the terminal device, and cause the terminal device to present the feedback information in a form understandable to an administrator, and
receive, from the terminal device, new design change information and iterative evaluation requests based on the feedback information, and rerun the numerical prediction processing and processing using the generative artificial intelligence model to support real-time optimization of the design.

### Supplementary 2

The system according to supplementary 1,
wherein the processor is configured to
describe, in the prompt sentence for input into the generative artificial intelligence model, an interview scenario including virtual subjects based on a plurality of user attributes and usage contexts, cause the generative artificial intelligence model to simulate responses of the plurality of virtual subjects to the design change, analyze contents of the simulated responses, and generate qualitative evaluation information to be included in the feedback information.

### Supplementary 3

The system according to supplementary 1,
wherein the processor is configured to
analyze the natural language response returned by the generative artificial intelligence model and the predicted values of the indicators calculated by the numerical prediction processing, reconstruct them as explanation information including graph information, summary text information, and specific design change proposal information, and output a prompt sentence that instructs presentation of the explanation information on the terminal device.

### Example 2

### Supplementary 1

A system comprising a processor,
wherein the processor is configured to
generate a prompt sentence that instructs analysis of an information structure related to a design and application of a statistical estimation process,
generate a prompt sentence that instructs collection of behavioral information related to a user operation history and evaluation of a usability index,
generate a prompt sentence that instructs analysis of difference information related to a design modification and prediction of an influence of the design modification on the usability index and the behavioral information,
acquire, from a storage apparatus, behavioral information related to the user operation history, and perform preprocessing of the behavioral information by using a data processing program, the preprocessing including at least completion of missing values and normalization,
generate a prompt sentence that instructs a generative AI model to analyze a usage tendency of a user on the basis of the preprocessed behavioral information and the usability index, and acquire an analysis result related to the usage tendency from the generative AI model, generate, on the basis of the acquired analysis result and the information structure related to the design, a configuration proposal of a user interface including at least arrangement, dimension, color, and other display attributes of a screen element, and transmit the configuration proposal to a user terminal, and
receive, from the user terminal, adoption information related to the configuration proposal and behavioral information related to the user operation history after application of the configuration proposal, and store the behavioral information in a form reusable for the preprocessing and for the analysis by the generative AI model.

### Supplementary 2

The system according to supplementary 1,
wherein the processor is configured to
generate a prompt sentence that instructs generation of an interview scenario including a dialogue scenario and question items for execution of a simulated qualitative interview by artificial intelligence on the basis of the preprocessed behavioral information and the usability index, and analysis of response content output by the generative AI model to extract insights related to subjective evaluations and latent requirements of the user.

### Supplementary 3

The system according to supplementary 1,
wherein the processor is configured to
generate a prompt sentence that specifies a summary content, an explanation content, and a visualization format for converting a prediction result and an analysis result returned by the generative AI model into at least a quantitative report format and a user interface improvement proposal format understandable to the user, and to cause presentation information generated according to the summary content, the explanation content, and the visualization format to be transmitted to the user terminal.

### Application Example 2

### Supplementary 1

A system comprising a processor,
wherein the processor is configured to
acquire usage data and store the usage data in a storage resource,
extract feature values representing usage tendency from the usage data and predict a user behavior index based on the feature values by using an information processing model,
acquire emotion-related data and identify a user emotion state from the emotion-related data, generate a prompt sentence for a generative AI model so as to cause the generative AI model to generate a screen configuration modification proposal or an information presentation method based on context information including the user behavior index and the user emotion state, and input the prompt sentence into the generative AI model,
convert the screen configuration modification proposal or the information presentation method output from the generative AI model into structured layout information and control a display screen presented to a user in accordance with the structured layout information, generate a prompt sentence for instructing analysis of each element of a design and application of prediction computation processing,
generate a prompt sentence for instructing collection of an operation history of the user and execution of usability evaluation processing, and
generate a prompt sentence for instructing analysis of design change content and evaluation of an influence caused by the design change content.

### Supplementary 2

The system according to supplementary 1,
wherein the processor is configured to
generate a prompt sentence for a generative AI model to instruct execution of simulated qualitative evaluation processing by artificial intelligence, the simulated qualitative evaluation processing including generation of an evaluation scenario comprising a virtual user attribute and a question content and extraction of insights from a group of response information generated based on the evaluation scenario.

### Supplementary 3

The system according to supplementary 1,
wherein the processor is configured to
generate a prompt sentence for instructing integration of a quantitative evaluation result returned by the generative AI model or the prediction computation processing and the insights, and presentation of a report information, which is based on the integrated result and is understandable to the user.

What is claimed is:

1. A system comprising:
circuitry configured to:
receive, from a terminal apparatus via a packet-switched network, configuration data representing a plurality of structured data elements and associated attribute values;
generate feature data by performing preprocessing on the configuration data, the preprocessing including at least quantization processing and normalization processing;
construct a first parameterized instruction sequence based on the feature data, the first parameterized instruction sequence specifying an analysis task for a generative neural network model to evaluate the structured data elements and apply a prediction algorithm to the feature data;
provide the first parameterized instruction sequence to the generative neural network model to cause the generative neural network model to generate quantitative evaluation data including predicted behavioral indicator values; and
generate report data based on the quantitative evaluation data and transmit the report data to the terminal apparatus via the packet-switched network.

2. The system according to claim 1, wherein the circuitry is further configured to:
acquire historical interaction data from a storage medium, the historical interaction data representing recorded operations performed by entities on a presentation interface, and construct a second parameterized instruction sequence instructing the generative neural network model to evaluate interaction efficiency metrics based on the historical interaction data.

3. The system according to claim 2, wherein the historical interaction data includes event type identifiers, event timestamp values, element identifiers corresponding to interacted elements, and session duration values, and wherein the circuitry computes aggregate behavioral statistics including interaction frequency values, mean session duration values, and element engagement ratio values from the historical interaction data.

4. The system according to claim 3, wherein the circuitry is further configured to:
receive modification data representing changes to the structured data elements, compute difference information between the configuration data and the modification data, and construct a third parameterized instruction sequence instructing the generative neural network model to predict an impact of the changes on the behavioral indicator values based on the difference information and the aggregate behavioral statistics.

5. The system according to claim 4, wherein the circuitry is further configured to:
extract the predicted behavioral indicator values from a prediction result generated by the generative neural network model, normalize the predicted behavioral indicator values as evaluation data associated with the modification data, and generate the report data comprising quantitative effect information and explanatory text data describing the predicted impact.

6. The system according to claim 5, wherein the circuitry is further configured to:
output presentation control data configured to cause the terminal apparatus to display the quantitative effect information and the explanatory text data in a time-series traceable format, enabling comparison of evaluation data across successive modification iterations.

7. The system according to claim 4, wherein the circuitry is further configured to:
input the feature data into a trained prediction model executed on a numerical computation device, the trained prediction model having an input layer corresponding to dimensions of the feature data, one or more hidden layers, and an output layer that computes predicted values of a plurality of performance indicators, and incorporate the predicted values into the parameterized instruction sequence for the generative neural network model.

8. The system according to claim 7, wherein the trained prediction model comprises a neural network trained using historical configuration data and corresponding historical behavioral indicator values as training data, with a loss function comprising at least a mean squared error component, and optimized using a gradient-based optimization algorithm.

9. The system according to claim 5, wherein the circuitry is further configured to:
generate scenario setting data including a plurality of entity attribute profiles and context conditions based on the modification data and the quantitative evaluation data, construct a simulation parameterized instruction sequence instructing the generative neural network model to generate simulated response data corresponding to each entity attribute profile, and analyze the simulated response data to generate qualitative evaluation data.

10. The system according to claim 9, wherein the circuitry is further configured to:
associate the qualitative evaluation data with the quantitative effect information to generate integrated assessment data, and transmit the integrated assessment data to the terminal apparatus for presentation.

11. The system according to claim 1, wherein the generative neural network model comprises a transformer-based architecture including an embedding layer, a plurality of self-attention layers, feed-forward layers, and normalization layers, and wherein the circuitry provides the parameterized instruction sequence as a token sequence to the transformer-based architecture together with decoding control parameters including a maximum output token count and a sampling temperature value.

12. The system according to claim 11, wherein the first parameterized instruction sequence includes a predetermined sentence structure specifying an analysis scope, target data element identifiers, evaluation criteria, and an output format specification requiring the generative neural network model to return the quantitative evaluation data in a machine-readable structured format.

13. The system according to claim 12, wherein the circuitry is further configured to:
select extraction conditions for extracting indicator values and explanatory elements from the prediction result according to an expression format of the prediction result, convert the prediction result into a machine-readable internal data structure based on the extraction conditions, and generate presentation content data based on the internal data structure.

14. The system according to claim 13, wherein the presentation content data includes at least one of graph specification data, summary text data, and specific modification proposal data derived from the quantitative evaluation data and the qualitative evaluation data.

15. The system according to claim 1, wherein the circuitry is further configured to:
acquire, from the storage medium, past modification history data corresponding to the configuration data and behavioral history data related to entity interactions, associate the past modification history data with the behavioral history data to construct learning input data, and perform preprocessing on the learning input data including completion of missing values and normalization to generate the feature data.

16. The system according to claim 15, wherein the circuitry is further configured to:
analyze the quantitative evaluation data and a natural language response from the generative neural network model, and generate feedback data including quantitative assessment information indicating an effect of the modification and a plurality of improvement option data items related to the modification.

17. The system according to claim 16, wherein the circuitry is further configured to:
receive, from the terminal apparatus, iterative evaluation request data based on the feedback data, and re-execute the prediction algorithm and the generative neural network model processing with updated modification data to support iterative optimization of the configuration data.

18. A system comprising:
circuitry configured to:
receive, via a communication interface coupled to a packet-switched network, configuration data representing structured data elements and modification data representing changes to the structured data elements from a terminal apparatus;
generate feature data by performing preprocessing on the configuration data including quantization and normalization, and compute difference information between the configuration data and the modification data;
construct a parameterized instruction sequence based on the feature data, the difference information, and historical interaction data acquired from a storage medium, and provide the parameterized instruction sequence to a generative neural network model having a transformer-based architecture including a plurality of self-attention layers to generate quantitative evaluation data including predicted behavioral indicator values;
extract the predicted behavioral indicator values, normalize the values as evaluation data, and generate report data comprising quantitative effect information and explanatory text data; and
transmit the report data to the terminal apparatus via the packet-switched network for presentation in a time-series traceable format.

19. The system according to claim 18, wherein the circuitry is further configured to:
generate scenario setting data based on the modification data, construct a simulation parameterized instruction sequence instructing the generative neural network model to generate simulated response data for a plurality of entity attribute profiles, analyze the simulated response data to generate qualitative evaluation data, and associate the qualitative evaluation data with the quantitative effect information for integrated presentation.

20. A method performed by circuitry, the method comprising:
receiving, from a terminal apparatus via a packet-switched network, configuration data representing a plurality of structured data elements and associated attribute values;
generating feature data by performing preprocessing on the configuration data, the preprocessing including at least quantization processing and normalization processing;
constructing a first parameterized instruction sequence based on the feature data, the first parameterized instruction sequence specifying an analysis task for a generative neural network model to evaluate the structured data elements and apply a prediction algorithm to the feature data;
providing the first parameterized instruction sequence to the generative neural network model to cause the generative neural network model to generate quantitative evaluation data including predicted behavioral indicator values; and
generating report data based on the quantitative evaluation data and transmitting the report data to the terminal apparatus via the packet-switched network.
